(19) United States
(12) Patent Application Publication
(10) Pub. No.: US 2005/0041752 A1
(43) Pub. Date: Feb. 24, 2005

(54) Pulse-shaped holographic communications apparatus and methods

(76) Inventor: Lowell Rosen, La Jolla, CA (US)

Correspondence Address: Robert F. Gazdzinski, Esq.;Gazdzinski & Associates, Suite 375, 11440 West Bernardo Court, San Diego, CA, 92127, US

(21) Appl. No.: 10/910,975

(22) Filed: Aug. 3, 2004

Related U.S. Application Data
(60) Provisional application No. 60/492,628, filed on Aug. 4, 2003.
(60) Provisional application No. 60/529,152, filed on Dec. 11, 2003.

(51) Int. Cl. H04L 27/02; H03C 1/52; H03C 5/00; H04L 27/00; H04L 27/30; H04B 15/00; H04B 1/713; H04B 1/707; H04B 1/69; H04K 1/00

(52) U.S. Cl. 375/268; 375/259; 375/130

(57) ABSTRACT

Improved apparatus and methods for utilizing holographic waveforms for a variety of purposes including communication, ranging, and detection. In one exemplary embodiment, the holographic waveforms are transmitted over an RF bearer medium to provide, inter alia, highly covert communications, radar systems, and microwave data links. The bearer (i.e., carrier) is optionally frequency-hopped, and various pulse modulation techniques applied in order to further increase communications efficiency and covertness including selective shaping of pulses associated with the holographic waveforms. Methods of providing multiple access and high bandwidth data transmission are also disclosed. Improved apparatus utilizing these features; e.g., a wireless miniature covert transceiver/locator, are also disclosed.

### PRIORITY AND RELATED APPLICATIONS

This application claims priority to co-owned U.S. Provisional Patent Application Ser. Nos. 60/492,628 filed Aug. 4, 2003 entitled “ENHANCED HOLOGRAPHIC COMMUNICATIONS APPARATUS AND METHOD” and 60/529,152 filed Dec. 11, 2003 and entitled “WIDEBAND HOLOGRAPHIC COMMUNICATIONS APPARATUS AND METHODS”, each incorporated herein by reference in its entirety, and is related to co-pending and co-owned U.S. patent application Ser. No. ______ entitled “FREQUENCY-HOPPED HOLOGRAPHIC COMMUNICATIONS APPARATUS AND METHOD” (Atty. Docket HOLOWAVE.002A), Ser. No. ______ entitled “MULTIPLE-ACCESS HOLOGRAPHIC COMMUNICATIONS APPARATUS AND METHODS” (Atty. Docket HOLOWAVE.002DV2), Ser. No. ______ entitled “EPOCH-VARIANT HOLOGRAPHIC COMMUNICATIONS APPARATUS AND METHODS” (Atty. Docket HOLOWAVE.002DV3), Ser. No. ______ entitled “REAL DOMAIN HOLOGRAPHIC COMMUNICATIONS APPARATUS AND METHODS” (Atty. Docket HOLOWAVE.002DV4) and Ser. No. 10/______ entitled “MULTIPATH-ADAPTED HOLOGRAPHIC COMMUNICATIONS APPARATUS AND METHODS” (Atty. Docket HOLOWAVE.002DV5), Ser. No. ______ entitled “MINIATURIZED HOLOGRAPHIC COMMUNICATIONS APPARATUS AND METHOD” (Atty. Docket HOLOWAVE.002DV6), and Ser. No. ______ entitled “HOLOGRAPHIC RANGING APPARATUS AND METHOD” (Atty. Docket HOLOWAVE.002DV7), all filed contemporaneously herewith, each of the foregoing incorporated herein by reference in its entirety. This application is also related to co-owned U.S. patent application Ser. No. 10/763,113 filed Jan. 21, 2004 entitled “HOLOGRAPHIC NETWORK APPARATUS AND METHODS”, U.S. Provisional Patent Application Ser. No. 60/537,166 filed Jan. 15, 2004 and entitled “APPARATUS AND METHODS FOR COMMAND, CONTROL, COMMUNICATIONS, AND INTELLIGENCE”, and co-owned U.S. patent application Ser. Nos. 10/868,420 entitled “WIDEBAND HOLOGRAPHIC COMMUNICATIONS APPARATUS AND METHODS” (Atty. Docket HOLOWAVE.004A), 10/868,433 entitled “SCALABLE TRANSFORM WIDEBAND HOLOGRAPHIC COMMUNICATIONS APPARATUS AND METHODS” (Atty. Docket HOLOWAVE.004DV1), 10/868,293 entitled “ADAPTIVE HOLOGRAPHIC WIDEBAND COMMUNICATIONS APPARATUS AND METHODS” (Atty. Docket HOLOWAVE.004DV2), 10/868,271 entitled “DIRECT CONVERSION HOLOGRAPHIC COMMUNICATIONS APPARATUS AND METHODS” (Atty. Docket HOLOWAVE.004DV3), 10/867,995 entitled “SOFTWARE-DEFINED WIDEBAND HOLOGRAPHIC COMMUNICATIONS APPARATUS AND METHODS” (Atty. Docket HOLOWAVE.004DV4) 10/867,794 entitled “ERROR-CORRECTED WIDEBAND HOLOGRAPHIC COMMUNICATIONS APPARATUS AND METHODS” (Atty. Docket HOLOWAVE.004DV5), and 10/868,316 entitled “HOLOGRAPHIC COMMUNICATIONS USING MULTIPLE CODE STAGES” (Atty. Docket HOLOWAVE.004DV6), all filed Jun. 14, 2004, each of the foregoing incorporated herein by reference in its entirety.

### Copyright

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

1. Field of the Invention

This invention relates generally to the field of communications, and more specifically to, inter alia, secure and covert modulated communications systems, such as those having the characteristics of random noise.

2. Description of Related Technology

Numerous types of radio frequency communications systems exist. These systems can be broadly categorized into narrowband or broadband systems. As the names imply, narrowband systems utilize one or more comparatively narrow portions of the RF spectrum, while broadband systems utilize one or more broad swaths of the spectrum.

Various air interfaces and spectral access techniques are used in narrowband and/or wideband systems including, for example, frequency division multiple access (FDMA), time division multiple access (TDMA), carrier sense multiple access, with our without collision detection (CSMA-CD), frequency hopping spread spectrum (FHSS), direct sequence spread spectrum (DSSS), orthogonal frequency division multiplexing (OFDM), and time-modulated (TM-UWB).

Each of the foregoing approaches has certain advantages and disadvantages depending on the application, but notably all suffer from several common disabilities including: 1) lack of covertness in the time and/or frequency domains; 2) lack of inherent robustness in the time and/or frequency domains; and 3) lack of inherent security. As used in this context, the term “inherent” means without other (e.g., higher layer) techniques such as encryption, forward error correction (FEC) or the like.

For example, in terms of covertness, transmitters of time modulated systems use a series of pulses emitted at substantially regular intervals (albeit slightly modulated), and FDMA and OFDM system transmitters have easily detected “stripes” in the frequency domain (corresponding to the various allocated frequency bands or output of the FFT⁻¹ process, respectively), and timing features in the time domain. DS/CDMA systems typically have a pilot channel or other identifiable artifacts within their radiated signal. FHSS systems hop at very precise intervals over a predictable band and a prescribed number of discrete channels, thereby making them non-covert. The regular Gaussian monopulses of the TM-UWB system are also readily detected, even at low levels of transmission. Well known correlation type receivers and analyzers can in effect make short work of detecting devices using these air interfaces.

In terms of security, a DSSS system such as CDMA uses a spreading code (including XOR mask) that is readily discoverable without higher layer encryption. Similarly, the hop sequence of an FHSS system can be determined, since most of these systems use a seeded pseudo-random sequence generator algorithm. OFDM and TM-UWB also require higher layer encryption protocols for any significant level of security. TDMA and FDMA, with regularly allocated time slots and frequency bands, provide effectively no security without higher layer encryption or similar protocols.

Furthermore, none of the aforementioned prior art techniques have inherent robustness or redundancy in both the time and frequency domains. Rather, each encounters significant problems when a portion of the signal in the time or frequency domain is lost (such as due to a narrowband or broadband jammer, Rayleigh fading, dropouts, interference, etc.). Again, error correction protocols such as well known Reed-Solomon or Turbo coding are needed to make these devices more operationally robust in the time and/or frequency domains.

Various other approaches to covert and/or secure communications systems are also evidenced in the prior art, each of the following patents incorporated herein by reference in its entirety. For example, U.S. Pat. No. 3,959,592 to Ehrat issued May 25, 1976 entitled “Method and apparatus for transmitting and receiving electrical speech signals transmitted in ciphered or coded form” discloses a method of, and apparatus for, transmitting and receiving electrical speech signals transmitted in ciphered form, wherein at the transmitter end there are formed in sections or intervals from the speech signals to be transmitted, by frequency analysis, signal components or parameter signals containing frequency spectrum-, voiced/voiceless information- and fundamental sound pitch coefficients, these signal components are ciphered, the ciphered signal components or parameter signals are transformed into a transmission signal and this transmission signal is transmitted over a transmission channel, and at the receiver end there is reobtained from the transmission signal the ciphered signal components or parameter signals and deciphered, and from the thus-obtained deciphered signal components or parameter signals there is generated by synthesis a speech signal which is similar to the original speech signal.

U.S. Pat. No. 4,052,565 to Baxter, et al. issued Oct. 4, 1977 and entitled “Walsh function signal scrambler” discloses a digital speech scrambler system allowing for the transmission of scrambled speech over a narrow bandwidth by sequency limiting the analog speech in a low-pass sequency filter and thereafter multiplying the sequency limited speech with periodically cycling sets of Walsh functions at the transmitter. At the receiver, the Walsh scrambled speech is unscrambled by multiplying it with the same Walsh functions previously used to scramble the speech. The unscrambling Walsh functions are synchronized to the received scrambled signal so that, at the receiver multiplier, the unscrambling Walsh signal is the same as and in phase with the Walsh function which multiplied the speech signal at the transmitter multiplier. Synchronization may be accomplished by time division multiplexing sync signals with the Walsh scrambled speech. The addition of the sync signals in this manner further masks the transmitted speech and thus helps to prevent unauthorized deciphering of the transmitted speech.

U.S. Pat. No. 4,694,467 to Mui issued Sep. 15, 1987 entitled “Modem for use in multipath communication systems” discloses a modem in which the transmitter uses spectrum spreading techniques applied to sequentially supplied input bits, a first group thereof having one spread spectrum sequence characteristic and a second group thereof having a different spread spectrum sequence characteristic, the spread spectrum bits being modulated and transmitted. The receiver generates complex samples of the received modulated signal at a baseband frequency and uses a detector for providing signal samples of the complex samples which are time delayed relative to each other. A selected number of the time delayed samples are de-spread and demodulated and the de-spread and demodulated samples are then combined to form a demodulated receiver output signal.

U.S. Pat. No. 4,817,141 to Taguchi issued Mar. 28, 1989 entitled “Confidential communication system” discloses apparatus where respective feature parameters extracted from a speech signal are converted into the corresponding line spectrum data in a first frequency band obtained by dividing the speech signal frequency band. Each of the line spectrum data is allocated previously to each one of the feature parameters. The extracted feature parameters are further converted into the corresponding line spectrum data in the other divided frequency bands other than the first frequency band. The converted line spectrum data are multiplexed for transmission. The corresponding line spectrum data in the divided frequency bands allocated to the same feature parameter are logically added to restore the feature parameters.

U.S. Pat. No. 4,852,166 to Masson issued Jul. 25, 1989 entitled “Analogue scrambling system with dynamic band permutation” discloses an analogue scrambling system with dynamic band permutation in which the speech signal is filtered, sampled at the rate fₑ, digitized, transformed by means of an analysis filter bank into N sub-band signals sampled at fₑ/N and transferred in a permuted order to a synthesis filter bank accomplishing the calculations of the scrambled signal sampled at the rate fₑ. A set of permutations is protected in a memory and a scrambling with dynamic permutation in time is obtained by changing the read addresses of the memory. The scrambled signal reconverted into an analogue signal is transmitted through an analogue channel to an unscrambler where it is preprocessed so that the synchronizing and equalizing functions are accomplished and where the accomplished processes are identical with those accomplished in the scrambler, the difference being that the permuted order of the N sub-band signals is restored.

U.S. Pat. No. 5,265,226 to Ueda issued Nov. 23, 1993 entitled “Memory access methods and apparatus” discloses a method of regenerating data convolutes plural data using maximal-sequence codes phase shifted by individual quantities and writes the convoluted data into a cyclic memory. A data regeneration apparatus reads out a desired data from the cyclic memory using a corresponding maximal-sequence code. Another method of regenerating data convolutes plural data using sequence codes for which are obtained weighting factors and maximal-sequence codes phase shifted by individual quantities and writes the convoluted data into a cyclic memory. Another data regeneration apparatus reads out a desired data from the cyclic memory using a corresponding maximal-sequence code. Still another method of regenerating data method convolutes plural data using maximal-sequence codes phase shifted by individual quantities and writes the convoluted data into a cyclic memory. Still another data regeneration apparatus reads out desired data from the cyclic memory using sequence codes which are obtained by weighting factors and maximal-sequence codes phase shifted quantities by individual.

U.S. Pat. No. 6,718,038 to Cusmario issued Apr. 6, 2004 entitled “Cryptographic method using modified fractional fourier transform kernel” discloses a cryptographic method that uses at least one component of a modified fractional Fourier transform kernel a user-definable number of times. For encryption, a signal is received; at least one encryption key is established, where each encryption key includes at least four user-definable variables that represent an angle of rotation, a time exponent, a phase, and a sampling rate; at least one component of a modified fractional Fourier transform kernel is selected, where each component is defined by one of the encryption keys; and the signal is multiplied by the at least one component of a modified fractional Fourier transform kernel selected. For decryption, a signal to be decrypted is received; at least one decryption key is established, where each decryption key corresponds with, and is identical to, an encryption key used to encrypt the signal; at least one component of a modified fractional Fourier transform kernel is selected, where each component corresponds with, and is identical to, a component of a modified fractional Fourier transform kernel used to encrypt the signal; and dividing the signal by the at least one component of a modified fractional Fourier transform kernel selected.

U.S. Pat. No. 6,728,306 to Shi issued Apr. 27, 2004 entitled “Method and apparatus for synchronizing a DS-CDMA receiver” discloses a system for synchronizing a DS-CDMA receiver to a received signal using actual data as opposed to a special training sequence. A chip by chip multiplication is applied to a sequence of received chip complex values in order to eliminate most traces of bit sign information from the received signal. The foregoing allows multiple bit length sequences of chips extracted from actual data to be combined, e.g., averaged, in order to reduce random noise. A low noise vector which has been derived from actual data can then be used to synchronize the receiver to a desired degree of precision.

Holography

Holography is a well-understood science wherein both intensity and phase information are captured within a medium, such where reference and object laser beams are used to capture the substantially randomized scattering of light from a three-dimensional object. Holography has been applied to a number of different applications such as radar and encryption, as evidenced by the following patents and publications, each of which are incorporated herein by reference in their entirety. For example, U.S. Pat. No. 4,924,235 to Fujisaka, et al. issued May 8, 1990 entitled “Holographic radar” discloses a holographic radar having receivers for amplifying, detecting, and A/D-converting the RF signals in all range bins received by antenna elements and a digital beamformer for performing digital operations on the outputs of these receivers to generate a number of beams equal to the number of antenna elements. Three or four antenna arrays (D0 to D3), each array being formed of a plurality of antenna elements, are oriented in different directions to provide 360-degree coverage and switches are provided to switch the connection between the antenna elements and the receivers according to pulse hit numbers and range bin numbers. Thus 360-degreecoverage can be attained with a small, inexpensive apparatus requiring as many receivers, memory elements and a digital beam former as needed for a single antenna array. The number of receivers can be further reduced by assigning one receiver per group of K array elements, providing memory elements, in number corresponding to the number of antenna elements, and operating further switches in synchronization with the transmit pulses and storing the video signals in the respective memory elements.

U.S. Pat. No. 5,734,347 to McEligot issued Mar. 31, 1998 entitled “Digital holographic radar” discloses apparatus producing a radar analog of the optical hologram by recording a radar image in the range/doppler plane, the range/azimuth plane, and/or the range/elevation plane according to the type and application of the radar. The invention embodies a means of modifying the range doppler data matrix by scaling, weighing, filtering, rotating, tilting, or otherwise modifying the matrix to produce some desired result. Specific examples are, removal of known components of clutter in the doppler frequency spectrum by filtering, and rotating/tilting the reconstructed image to provide a view not otherwise available. In the first instance, a reconstructed image formed after filtering the Fourier spectrum would then show a clutter free replication of the original range/PRI object space. The noise floor can also be modified such that only signals in the object space that produce a return signal above the ‘floor’ will be displayed in the reconstructed image.

U.S. Pat. No. 5,793,871 to Jackson issued Aug. 11, 1998 entitled “Optical encryption interface” discloses an analog optical encryption system based on phase scrambling of two-dimensional optical images and holographic transformation for achieving large encryption keys and high encryption speed. An enciphering interface uses a spatial light modulator for converting a digital data stream into a two dimensional optical image. The optical image is further transformed into a hologram with a random phase distribution. The hologram is converted into digital form for transmission over a shared information channel. A respective deciphering interface at a receiver reverses the encrypting process by using a phase conjugate reconstruction of the phase scrambled hologram.

U.S. Pat. No. 5,940,514 to Heanue, et al. issued Aug. 17, 1999 entitled “Encrypted holographic data storage based on orthogonal phase code multiplexing” discloses an encryption method and apparatus for holographic data storage. In a system using orthogonal phase-code multiplexing, data is encrypted by modulating the reference beam using an encryption key K represented by a unitary operator. In practice, the encryption key K corresponds to a diffuser or other phase-modulating element placed in the reference beam path, or to shuffling the correspondence between the codes of an orthogonal phase function and the corresponding pixels of a phase spatial light modulator. Because of the lack of Bragg selectivity in the vertical direction, the phase functions used for phase-code multiplexing are preferably one dimensional. Such phase functions can be one-dimensional Walsh functions. The encryption method preserves the orthogonality of reference beams, and thus does not lead to a degradation in crosstalk performance.

U.S. Pat. No. 6,288,672 to Asano, et al. issued Sep. 11, 2001 and entitled “Holographic radar” discloses apparatus wherein high-frequency signals from an oscillator are transmitted, through a power divider and a switch, from transmission antennas (T1, T2, T3). Reflection waves reflected by targets are received by reception antennas (R1, R2) to thereafter be fed via a switch to a mixer. The mixer is supplied with transmission high-frequency signals from the power divider to retrieve beat-signal components therefrom, which in turn are converted into digital signals for the processing in a signal processing circuit. The transmission antennas (T1 to T3) and the reception antennas (R1, R2) are switched in sequence whereby it is possible to acquire signals equivalent to ones obtained in radars having a single transmission antenna and six reception antennas.

U.S. Pat. No. 6,452,532 to Grisham issued Sep. 17, 2002 entitled “Apparatus and method for microwave interferometry radiating incrementally accumulating holography” discloses a satellite architecture and method for microwave interferometry radiating incrementally accumulating holography, used to create a high-gain, narrow-bandwidth actively-illuminated interferometric bistatic SAR whose VLBI has a baseline between its two bistatic apertures, each on a different satellite, that is considerably longer than the FOV, in contrast to prior art bistatic SAR where the interferometer baseline is shorter than the FOV. Three, six, and twelve satellite configurations are formed of VLA satellite VLBI triads, each satellite of the triad being in its own nominally circular orbit in an orbital plane mutually orthogonal to the others of the triad. VLBI pairs are formed by pairwise groupings of satellites in each VLA triad, with the third satellite being used as a control satellite to receive both Michelson interferometric data for phase closure and Fizeau interferometric imaging data that is recorded on a holographic disc, preserving phase.

U.S. Pat. No. 6,469,672 to Marti-Canales, et al. issued Oct. 22, 2002 entitled “Method and system for time domain antenna holography” discloses a method which permits determination of the electrical features of an antenna. The antenna is excited with an ultra-short voltage pulse and the far field radiation pattern of the antenna is measured. The resulting time-varying field distribution across the antenna aperture is then reconstructed using time domain holography. A direct analysis of the holographic plot permits the determination a wide range of electrical properties of the antenna.

U.S. Pat. No. 6,608,708 to Amadon, et al. issued Aug. 19, 2003 entitled “System and method for using a holographic optical element in a wireless telecommunication system receiver” discloses a holographic optical element (HOE) device mounted in a receiver unit, such as a wireless optical telecommunication system receiver. The HOE device includes a developed emulsion material having an interference pattern recorded thereon, sandwiched between a pair of elements, such as a pair of clear glass plates. In operation, the HOE device uses the recorded interference pattern to diffract incident light rays towards an optical processing unit of the system receiver. The optical processing unit includes a photodetector that detects the diffracted light rays. The system receiver can include various other components and/or can have various configurations. In one configuration, a plurality of mirrors is used to control the direction of the light rays coming from the HOE device, and a collimating optical assembly collimates these light rays. A beam splitting optical assembly can be used to split the light rays into a tracking channel and a communication channel.

U.S. Patent Application Publication No. 20030179150 to Adair, et al. published Sep. 25, 2003 entitled “HOLOGRAPHIC LABEL WITH A RADIO FREQUENCY TRANSPONDER” discloses a label for identifying an object includes a radio frequency transponder and a hologram. The radio frequency transponder has an antenna and a transponder circuit sandwiched between two layers of material which form exterior surfaces of the transponder. The hologram comprises a first layer of non-metallic material applied to one of the exterior surfaces and forming a non-metallic reflector of light. A generally transparent second layer contains a holographic image and extends across the first layer. Because the reflective first layer is made of a non-metallic material, its close proximity to the radio frequency transponder does not detune the transponder as may occur when metallic holograms are placed in close proximity to the transponder. Thus the hologram provides a deterrent to unauthorized use of the label without affecting the operation of the radio frequency transponder.

U.S. Patent Application Publication No. 20030184467 to Collins published Oct. 2, 2003 entitled “APPARATUS AND METHOD FOR HOLOGRAPHIC DETECTION AND IMAGING OF A FOREIGN BODY IN A RELATIVELY UNIFORM MASS” discloses an apparatus and method for displaying a foreign body in a relatively uniform mass having similar electromagnetic impedance as the foreign body comprising of at least two ultra wide band holographic radar units adapted to generate, transmit and receive a plurality of 12-20 GHz frequency signals in a dual linear antenna with slant-angle illumination. The invention may be utilized to obtain qualitative and quantitative data regarding the composition of the object under investigation.

Despite the foregoing variety of approaches to radio frequency communications, no practical system having (i) covertness in both the time and frequency domains, (ii) inherent redundancy in the time and frequency domains, and (iii) inherent security, has been developed.

Hence, there is a salient need for an improved communications system that provides each of the foregoing features and benefits. Such improved apparatus and methods would also ideally allow for multiple access as well as high data rates over the air interface, all without significant higher layer protocol support, and would be readily implemented in existing hardware. Such solution also ideally could be adapted to other media and paradigms, including e.g., acoustics, wireline applications, and even matter waves.

### SUMMARY OF THE INVENTION

The present invention satisfies the foregoing needs by providing improved communications apparatus and methods which utilize holographic signal processing.

In a first aspect of the invention, improved radio frequency communications apparatus adapted to holographically encode baseband data and transmit the encoded data is disclosed. In one embodiment, the holographically encoded data is distributed (e.g., frequency-hopped) across a plurality of frequencies as a function of at least time during the transmitting. In another embodiment, the holographic encoding comprises generating real and imaginary waveforms disposed in substantially non-overlapping first and second frequency bands, and the distribution across a plurality of frequencies as a function of at least time comprises hopping each of the real and imaginary waveforms across a first plurality of frequencies and a second plurality of frequencies, respectively, within respective ones of the first and second non-overlapping frequency bands.

In a second aspect of the invention, improved radio frequency communications apparatus adapted to receive and decode holographically encoded signals that are hopped across a plurality of frequencies is disclosed. In one embodiment, the hopping comprises distributing each of real and imaginary waveforms across respective different sets of frequencies, and the de-hopping comprises recovering the distributed waveforms therefrom.

In a third aspect of the invention, improved radio frequency apparatus adapted to holographically encode baseband data from a first plurality of data sources and a second plurality of data sources, and transmit the encoded data is disclosed. In one embodiment, data from the first plurality of sources is used to form a first holographically encoded waveform, and data from the plurality of sources is used to form a second holographically encoded waveform. The first and second holographically encoded waveforms are each distributed across a plurality of frequencies as a function of at least time during the transmitting.

### BRIEF DESCRIPTION OF THE DRAWINGS

The features, objectives, and advantages of the invention will become more apparent from the detailed description set forth below when taken in conjunction with the drawings, wherein:

FIGS. 1a and 1b are graphical representations of Gaussian and exemplary binary pulsed waveforms, respectively, according to the invention.

FIGS. 2a and 2b are graphical representations of Gaussian and exemplary “sharp” (short duration) pulsed waveforms, respectively, according to the invention.

FIGS. 3a and 3b are functional block diagrams of exemplary multi-user holographic transmitter and receiver processes, respectively, according to the invention.

FIGS. 3c-3e are functional block diagrams illustrating three different embodiments of transceiver apparatus useful for transmitting and receiving the holographically encoded waveforms of the present invention.

FIGS. 4a and 4b are functional block diagrams of exemplary multi-data page holographic transmitter and receiver processes, respectively, according to the invention.

FIG. 4c is a functional block diagram of exemplary approach for registering data structures (e.g., frames) in the receiver using a power spectrum.

FIG. 5 is a graphical representation of an exemplary “all-real” phase coder according to the invention.

FIGS. 6a and 6b are graphical representations of one-channel (one data, one reference) and exemplary two-channel (two data channels with Sin(x)/x distribution) pulsed waveforms, respectively, according to the invention.

FIGS. 7a and 7b are graphical representations of an exemplary embodiment of a multi-path distortion removal technique according to the invention.

FIG. 8 is a front perspective view of an exemplary embodiment of a portable miniature transceiver device according to the invention.

FIG. 8a is a functional block diagram of one exemplary component architecture of the transceiver device of FIG. 8.

FIG. 8b is a graphical representation of an exemplary software-controlled radio architecture useful with the present invention.

### DETAILED DESCRIPTION OF THE PREFERRED EMBODIMENT

Reference is now made to the drawings wherein like numerals refer to like parts throughout.

As used herein, the terms “hologram” and “holographic” refer to any waveform, regardless of physical medium (e.g., electromagnetic, acoustic/sub-acoustical or ultrasonic, matter wave, gravity wave, etc), which has holographic properties.

As used herein, the term “digital processor” is meant generally to include all types of digital processing devices including, without limitation, digital signal processors (DSPs), reduced instruction set computers (RISC), general-purpose (CISC) processors, reconfigurable compute fabrics (RCFs), processor arrays, microprocessors, and application-specific integrated circuits (ASICs) and even all-optical processors using lasers. Such digital processors may be contained on a single unitary IC die, or distributed across multiple components. Exemplary DSPs include, for example, the Motorola MSC-8101/8102 “DSP farms”, Motorola MRC6011 RCF, the Texas Instruments TMS320C6x, or Lucent (Agere) DSP16000 series.

As used herein, the term “display” means any type of device adapted to display information, including without limitation CRTs, LCDs, TFTs, plasma displays, LEDs, and fluorescent devices.

As used herein, the term “baseband” refers to the band of frequencies representing an original signal to be communicated or any portion or derivation thereof.

As used herein, the term “carrier wave” refers to the electromagnetic or other wave on which the original signal is carried. This wave has a frequency or band of frequencies (as in spread spectrum) selected from an appropriate band for communications transmission or other functions (such as detection, ranging, etc.).

As used herein, the terms “up-conversion” and “down-conversion” refer to any increase or decrease, respectively, in the frequency of a signal.

It is noted that while portions of the following description are cast in terms of RF (wireless) communications applications, the present invention may be used in conjunction with any number of different bearer mediums and topologies (as described in greater detail subsequently herein). Accordingly, the following discussion is merely exemplary of the broader concepts of the invention.

Overview

Co-owned U.S. Pat. No. 4,972,480, issued Nov. 20, 1990 and entitled “Holographic Communications Device and Method” (hereinafter “the '480 patent”), which is incorporated herein by reference in its entirety, discloses an improved secure and covert modulated radio frequency communications system of a holographic nature. This system was designed to produce transmissions having the characteristics of Gaussian, zero-mean and stationary random noise and a high degree of information redundancy characteristic of diffuse image holograms. In effect, it produces a signal appearing as noise in both the time and frequency domains. Desirable characteristics of the basic holographic technology include: (i) a high degree of covertness; (ii) a lack of data frame registration (i.e., the inverse Fourier Transform of F(t) is f(w), therefore the inverse transform of F(t−T) is f(w)e^{iwT}, where F(t−T) is the delayed hologram frame, and f(w)e^{iwT} is the registered baseband frame which is frequency shifted); (iii) rapid receiver acquisition and de=spreading (due to aforementioned lack of registration); (iv) great channel robustness (i.e., hologram RF signals can survive very high percentage losses (50%-90%) through inherent redundancy afforded by convolution of code and baseband spectrums); and (v) the ability to receive and decode parts of multiple holograms (i.e., hologram received in receiver time window t is F′₁(t−T₁)+F′₂(t−T₂), with baseband of f₁(w)^{eiwT}₁+f₂(w)^{eiwT}₂; multiplication by e^{-1Code1} de-spreads frame 1, while frame 2 appears as wideband noise, and a narrowband filter can be used to recover frame 1).

While the technology of the '480 patent is clearly useful and provides many intrinsic benefits as described, further improvements are possible, and the technology expanded in terms of the scope and types of applications with which it may be used.

Accordingly, the present invention provides several enhancements and improvements to the basic technology disclosed in the '480 patent, as well a variety of new applications therefor. Such enhancements include, inter alia, the use of a spectrum spreading techniques (e.g., frequency hopping spread spectrum, or FHSS), and use of multiple baseband modulations including, e.g., frequency modulation, amplitude modulation, various types of pulse modulation, etc., for the purpose of adding a multitude of simultaneous users and a multitude of simultaneous “pages” of information all within a single covert and noise-like transmission.

Furthermore, the present invention also teaches an improved technique by which more information can be carried on the waveform through assignment of the dc baseband channel (described in the '480 patent) to an information-modulated waveform.

Yet further enhancements include the use of random time-dithered waveforms, to foil eavesdroppers using correlation-based intercept receivers.

New uses of the holographic technology include the application to other information carrying sources of energy such as coherent and incoherent light sources, x-rays, and even gamma rays, mechanical sources of energy (such as acoustical and other sonic waves outside the range of human hearing), and finally to matter waves such as subatomic particle beams such as neutrons. This broad range of media allows the technology to be applied to e.g., any number of communications, radar, and sonar-based devices and even transmission through solid materials such as steel plates or building structures.

Enhancements to Holographic Technology

The output radio frequency waveforms of the '480 patent are generally confined to the bandwidth established by the baseband signals and the modulating noise waveform. Although this may be sufficient for many applications, certain uses (e.g., military, or high density civilian communications systems such as those used in a metropolitan area) generally require a wider spread of bandwidths. Accordingly, one aspect of the present invention applies a frequency hopping approach to the radio hologram output waveform. Frequency hopping is a well known RF spread-spectrum technique wherein, e.g., a pseudo-random hop sequence is generated by a seeded algorithm, the sequence being dependent in large part on the seed. The carrier accordingly hops from one frequency to the next, disposing either more (“fast” FHSS) or less than (“slow” FHSS) one temporal “chip” of data (e.g., bit, byte, etc., typically measured in the temporal hop duration) per hop. The receiver is synchronized to the same sequence, such as by using a similar pseudo-random algorithm and “seed”.

In the context of the present invention, frequency hopping of the hologram output waveform advantageously spreads the frequency bandwidth further than without such hopping, up to a total bandwidth of more than 1 GHz if desired. This increases the processing gain of the holographic waveform by a factor proportional to the ratio of the frequency hopped bandwidth and the holographic waveform bandwidth. Accordingly, the frequency-hopped holographic signal has enhanced resistance to jamming, and additional covertness, since the holographic signal (already LPI) is now distributed in effectively discrete temporal “chips” across a broad range of frequencies. In the exemplary embodiment, multiple (n) hops per second are used (hop period=1/n sec.), with R discrete hop bands of S MHz each (which may be contiguous or non-contiguous within the frequency spectrum), although other values may be used. For example, values of 1000, 100, and 1 might be used for n, R, and S, respectively, although other values (including those in the “slow” FH domain) may be used if desired. In the exemplary embodiment, S is chosen to encompass all or nearly all of the non-hopped holographic signal bandwidth. Any number of different hopping algorithms may be used consistent with the present invention, the creation and use of which are well known in the communications arts and accordingly not described further herein.

Additionally, the hopping may occur separately within one or both of the real and imaginary frequency bandwidths of the holographically encoded waveforms. For example, one embodiment of the present invention encodes two waveforms; i.e., real and imaginary, as described in detail in the '480 patent referenced above. These waveforms can be transmitted over substantially non-overlapping frequency bandwidths each having a plurality of assigned carriers therein (or even overlapping bands, realizing that some “collisions” in frequency-time space will occur, thereby causing some dropouts of data, although these dropouts are tolerable as in a conventional FHSS system where multiple users assigned different hop codes occasionally collide in time-frequency space without significant deleterious effect).

In the non-overlapping variant, the same hop code or sequence may even be used for both real and imaginary waveforms; however, different hop codes are typically preferred to avoid any beats or other correlations between the two offset frequency bandwidths containing the carriers for the real and imaginary waveforms, respectively.

In the overlapping variant, the hop codes may be the same, although they must be offset or staggered in time or in frequency to avoid constant collisions. This approach may produce beats or correlations, however; hence, it is more preferable to use two pseudo-randomized codes that have no relation to one another, and which will merely collide on occasion as described above.

Additionally, it will be recognized that multiple “user” access can be provided using different frequency hopping codes. As is well known in prior art FHSS systems, multiple users of a system are each given a different pn or hopping code, and only limited or incidental collisions occur (at least at a reasonable number of users). Hence, each user's waveforms are hopped across the same set of carriers as the other users, just at different times and in a different sequence. As channel capacity is reached, more and more collisions occur, thereby providing a somewhat “graceful” degradation in quality. As will be described in detail subsequently herein, multiple access in the holographic transmitter system of the present invention may be provided using baseband frequency offsets and/or different phase codes before transformation. The transformed and transmitted (holographic) waveforms, however, look practically identical to those with only one user. Hence, if the “single user” waveforms described above as part of the exemplary embodiment can be hopped over the carrier frequency domain, so can the functionally identical “multiple access” holograms. From the perspective of the hopping algorithm(s), the fact that the holograms are single- or multi-user is of no moment. Similarly, by extension, the carrier-domain multiple access scheme described above is indifferent to whether the holograms are single- or multi-user. Therefore, a “multiple-access over multiple-access” (MA²) capability is provided by the present invention; specifically, multiple sets of waveforms being multiple-accessed in the baseband domain are hopped together into the carrier domain.

In one such variant, a first set of users (U1ₐ . . . U1ₙ) is given a first common phase code, with each user having a different baseband frequency offset as discussed below. A second set of users (U2ₐ . . . U2ₙ) is given a second different common phase code, with each user having a different baseband frequency offset. The baseband processing for each of the two sets of users (U1 and U2), which may be accomplished using different or the same baseband processor(s), converts each set of user data into respective holographic waveforms H1 and H2 (each having, e.g., real-only or real and imaginary components as desired). H1 and H2 are then hopped onto one or more sets of carriers according to respective hopping codes pn1 and pn2 (pn1 and pn2 ideally being at least partly orthogonal). The baseband processing for H1 and H2 may comprise the same or a connected physical device (such as where U1 and U2 comprise sets of data “pages” as described subsequently herein), or alternatively may be distributed across two or more discrete hardware environments (such as different transmitters for each individual user).

It will be further recognized that other types of frequency hopping may be used consistent with the invention, including for example so-called “adaptive frequency hopping” (AFH). AFH is a method for avoidance of fixed frequency interferers. AFH techniques as used in the present invention might comprise for example one or more of three (3) primary components; i.e., (i) Channel Classification—detecting an interfering source on a channel-by-channel basis; (ii) Hop Sequence Modification—avoiding the interferer by selectively reducing the number of hopping channels or altering the sequence; and (iii) Channel Maintenance—periodically re-evaluating the channels. Channel classification involves the detection of the interfering network. There are various methods well known in the communications arts to accomplish this, such as for example RSSI measurements, number of consecutive packet errors, packet error averages, etc. See, e.g., U.S. Pat. No. 6,084,919 to Kleider, et al. issued Jul. 4, 2000 entitled “Communication unit having spectral adaptability” and assigned to Motorola Inc., which is incorporated herein by reference in its entirety.

Regardless of the classification technique, metrics of channel quality are stored, such as on a channel-by-channel basis. These metrics are then used to classify each channel (e.g., as being either acceptable or non-acceptable, or according to some other non-fuzzy or fuzzy rating scale or scoring algorithm). Once the new (pool of) good channels has been determined, each device modifies its “hopset” in order to avoid unacceptably noisy or interfering channels. This modification of the hopping set (e.g., via its seed) is synchronized (in time and frequency) between any devices wishing to carry on communications. The foregoing process of channel classification and modification may be performed periodically (channel maintenance), such as at prescribed intervals, or upon the occurrence of one or more events, such as encountering an increased density of “noisy” channels, etc.

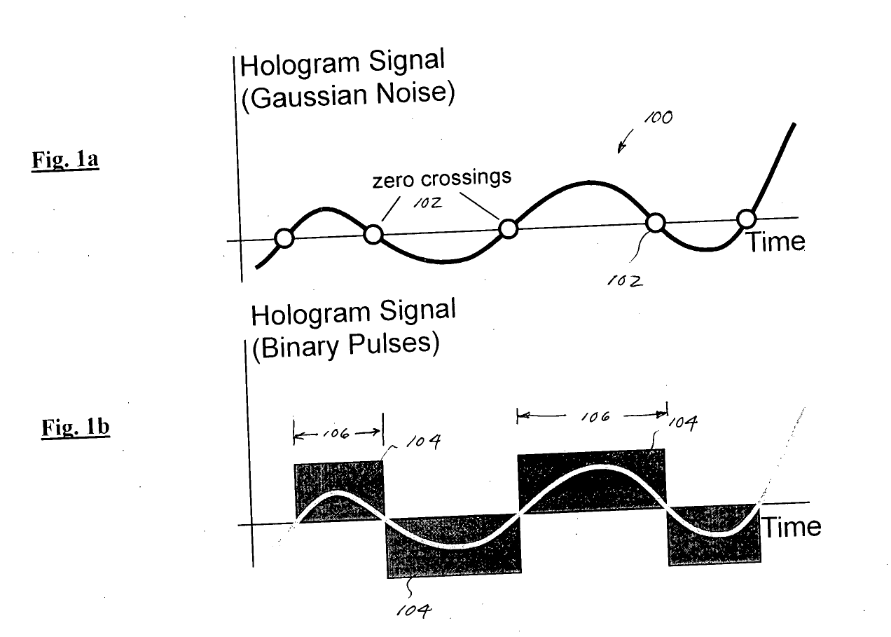

As shown in FIG. 1a, the basic transmitted holographic waveform 100 has the appearance of wideband Gaussian noise. As a holographic signal, the information contained within it lies mainly in the zero-crossings 102 of the signal. Another enhancement provided by the present invention comprises clipping (or enveloping) the output waveform before transmission, and converting it into random, binary signals 104 of plus and minus pulses of equal amplitude, but with random duration 106 (see FIG. 1b). Such clipping or enveloping can be accomplished by any number of different apparatus (high-speed analog or even digital) known to those of ordinary skill, and hence is not described further herein. Such clipping or enveloping may be conducted entirely in the baseband if desired, or alternatively at least partly in the analog IF or RF domain (such as using an envelope tracker and shaper circuit). Advantageously, the zero-crossings 102 are left intact. In this form, the transmission can be mixed with other non-covert digital transmissions if desired to hide it or even disrupt those other transmissions. Based on the holographically-related redundancy of the signal, even degradation of the signal created by such “mixing” can be overcome while still being able to recover baseband data.

Another enhancement provided by the present invention comprises use of the previously discussed binary signal generation, but alters the amplitude of each binary pulse from the previous constant plus (+) and minus (−) amplitudes to binary pulses of varying amplitude according to the average of the non-binary holographic waveform between zero crossings. Hence, the amplitude of each pulse varies as a function of the holographic waveform between zero crossings.

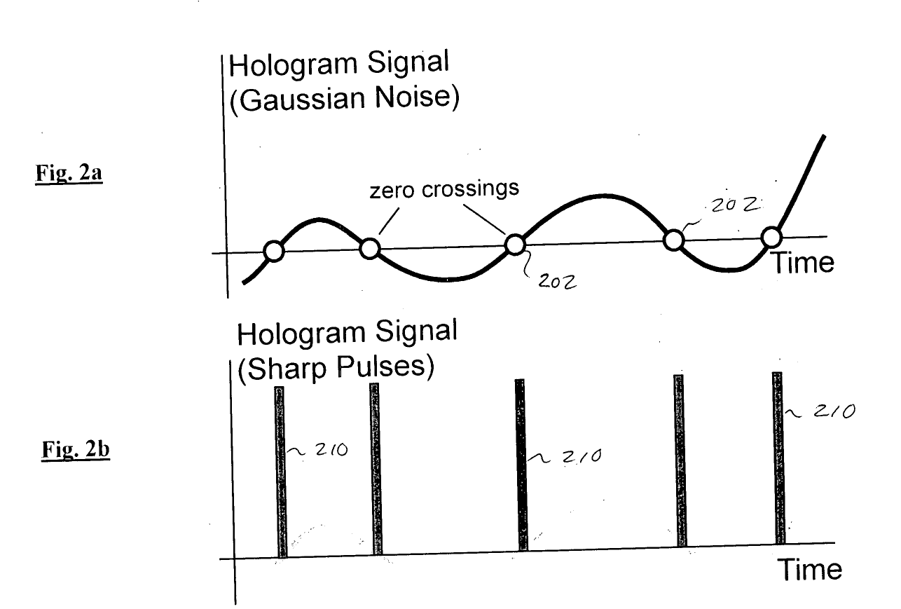

Referring now to FIGS. 2a and 2b, yet another improvement provided by the present invention is described. Specifically, in the illustrated embodiment of FIG. 2b, a waveform containing “sharp” (short temporal duration, e.g. 10 ns, 1 ns, 0.1 ns), high-bandwidth pulses 210 of uniform or varying amplitude occurring at the zero-crossings 202 of the original output waveform is used. Varying pulse amplitudes can be, e.g., proportional to the difference in average values of the non-binary holographic waveform between successive zero crossings as previously described. This approach increases the spread bandwidth. This signal, when received, can be reconstituted as a binary holographic signal from which the baseband can be retrieved. These sharp pulses 210 are not on the baseband signal, but rather on the holographic transmitted waveform. This approach uses the sharp pulse feature somewhat akin to current time-modulated ultra-wideband (TM-UWB) technology and its Gaussian monopulses, but in the context of the holographic waveform as opposed to modulating the pulse position in time to encode data. It will also be appreciated that while “sharp” pulses are described in the illustrated embodiment, other pulse shapes may be used consistent with the invention, and for such reasons as shaping of the transmitted bandwidth or waveform. For example, short duration Gaussian pulses may be utilized, as well as other pulse waveforms. The pulse amplitude may be varied or modulated as desired also.

It will further be recognized that the foregoing techniques can be used in isolation or jointly as desired. For example, a FHSS system employing waveform clipping/enveloping as described above may be made. Alternatively, a “sharp” pulsed FHSS system may be used.

The aforementioned techniques can be temporally intermixed as well, such as by utilizing “sharp” pulses for a period of time, then clipped/enveloped pulses, etc. The “hopping” between (and duration of each instantiation of) these different pulse forms can be controlled by a second (and even third) pseudo-random algorithm akin to that utilized for the spectral access spreading described above, in order to randomize the transitions and duration of each interval. In this fashion, synchronization between transmitter and receiver is not significantly more difficult than that for the FHSS approach. Hence, a triple-domain hopping approach is contemplated, wherein (i) the carrier frequency is hopped as previously described (first domain); (ii) the pulse modulation type is hopped between two or more alternatives (second domain); and (iii) the temporal duration of each modulation type is hopped (third domain). These three hopping domains may also be controlled by one hop algorithm for simplicity if desired.

Permutation or coding of the type well known in CDMA or other systems can also be optionally employed if desired to reduce BER on pulse modulation transitions (i.e., where one or more bits of data may be lost on the transmitter/receiver shifting from one modulation scheme to the other); by moving these “lost” bits around in the transmitted data stream, their effect will be inconsequential. Furthermore, as the phase coding rate is increased, such effects would be mitigated since multiple “copies” of each bit are encoded into the holographic waveform at different spectral values.

Well known interleaver schemes (such as so-called “natural order” interleavers, and those implementing interleaving via a pn or comparable sequence) may also be used consistent with the invention either alone or in combination. For example, a pseudo-random constant-relationship interleaver generally akin to that described in U.S. Patent Application 20020029364 to Edmonston, et al. published Mar. 7, 2002 and entitled “System and method for high speed processing of turbo codes”, incorporated herein by reference in its entirety, may be used consistent with the present invention. It will also be appreciated that traditional Turbo coding may be used consistent with the invention, such as that described in U.S. Pat. No. 5,446,747 to Berrou issued Aug. 29, 1995 entitled “Error-correction coding method with at least two systematic convolutional codings in parallel, corresponding iterative decoding method, decoding module and decoder” incorporated herein by reference in its entirety, which discloses an error-correction method for the coding of source digital data elements to be transmitted or broadcast, notably in the presence of high transmission noise. The Berrou (Turbo code) method comprises at least two independent steps of systematic convolutional coding, each of the coding steps taking account of all of the source data elements, at least one step for the temporal interleaving of the source data elements, modifying the order in which the source data elements are taken into account for each of the coding steps, and a corresponding iterative decoding method that, at each iteration, obtains an intermediate data element through the combination of the received data element with a data element estimated during the previous iteration.

When coupled with the intrinsically noise-like signals by the basic holographic technique, this processing in effect presents an unintelligible mixture of communications signals to any potential interceptor. Only explicit knowledge of all three hop algorithms (and any permutation or convolution codes used) will allow detection and decoding. Since the hop sequences are all effectively randomized, the radiated energy appears substantially “white” as well.

The foregoing is merely exemplary; numerous different permutations of these features of the invention are possible, such combinations being readily implemented by those of ordinary skill in the wireless spread spectrum communications arts given the present disclosure.

Adding Multiple Users and Pages Simultaneously

The process of having multiple users communicate simultaneously within a spread spectrum bandwidth is a major feature of modem cellular technology such as CDMA (Code Division Multiple Access), and also of the present invention. In one exemplary embodiment of the present invention, each user effectively produces their own waveform, with a different pn or pseudo-random scrambling code being assigned for each user. The codes are at least substantially orthogonal, thereby providing (i) so-called “graceful degradation” as the channel capacity is reached, and (ii) for easy separation of users from one another when operating at less than capacity. Hence, each user's baseband data is phase coded according to a different sequence, and then added and Fourier (or other) transformed to produce the holographic waveforms. At the receiver, these waveforms are inverse transformed, and then de-spread using the same phase codes.

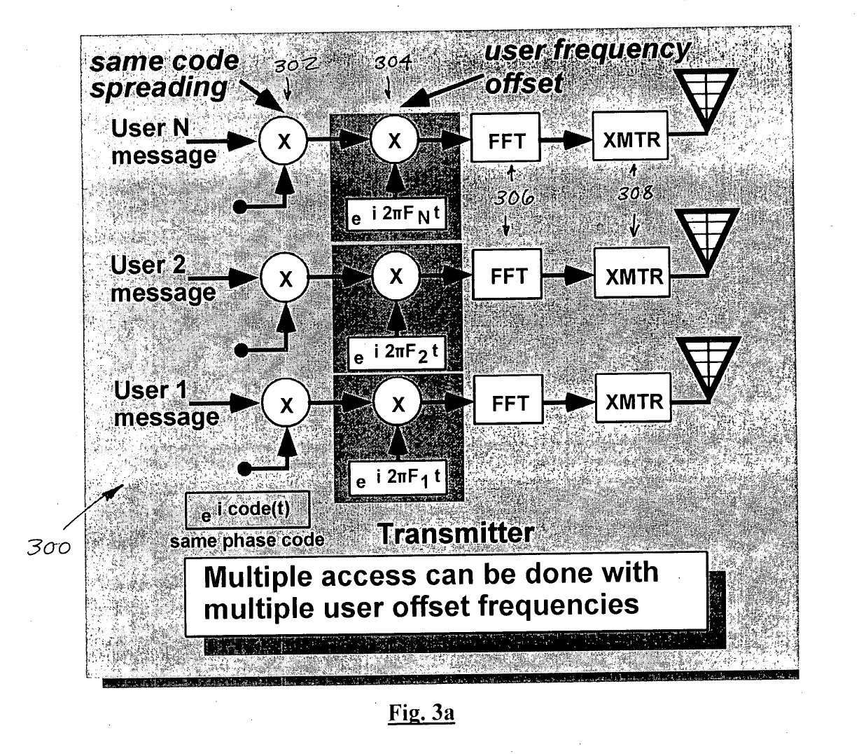

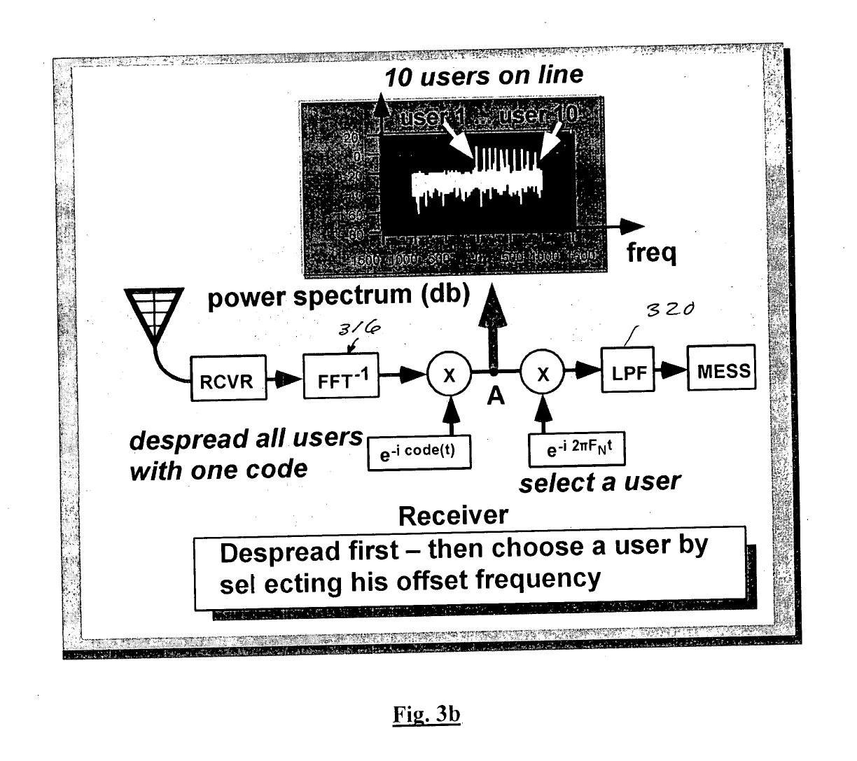

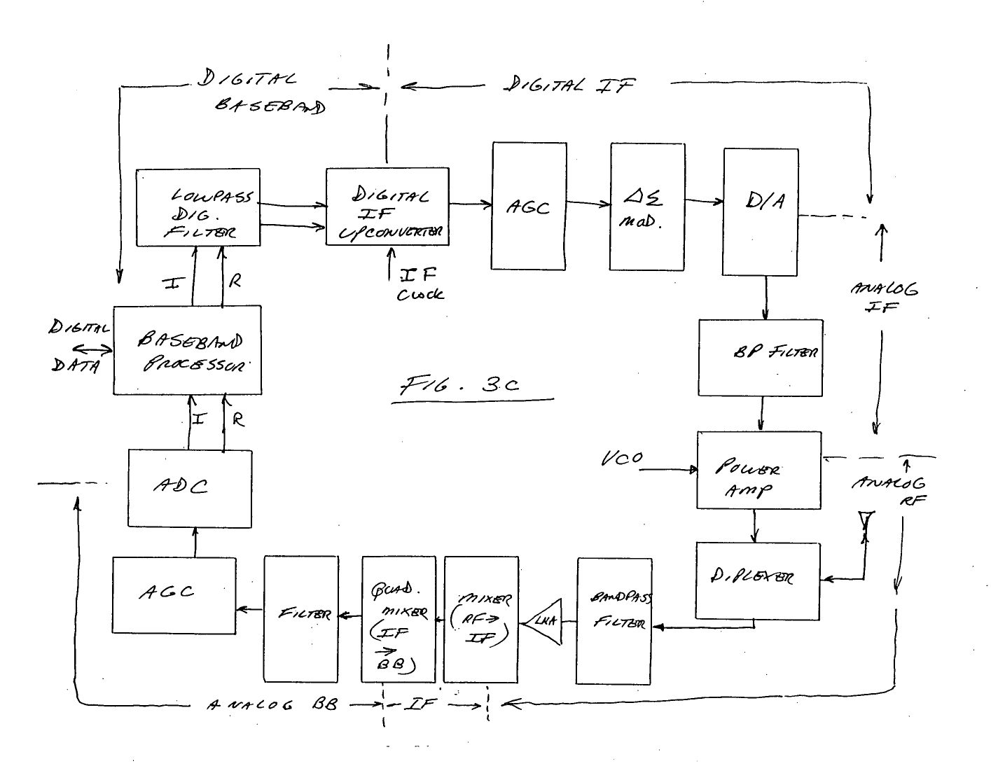

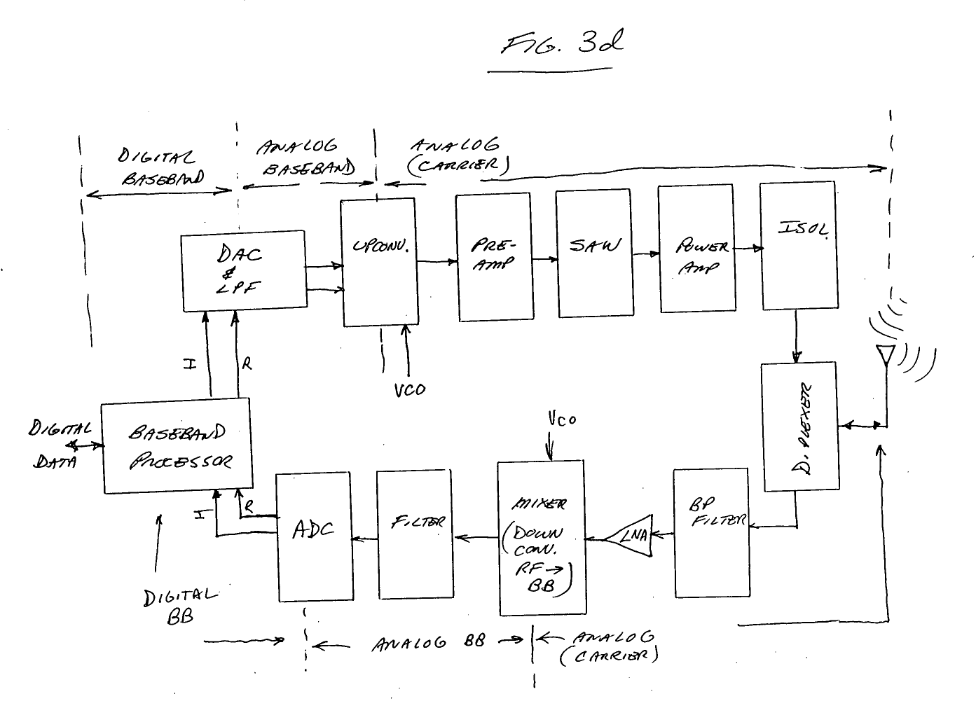

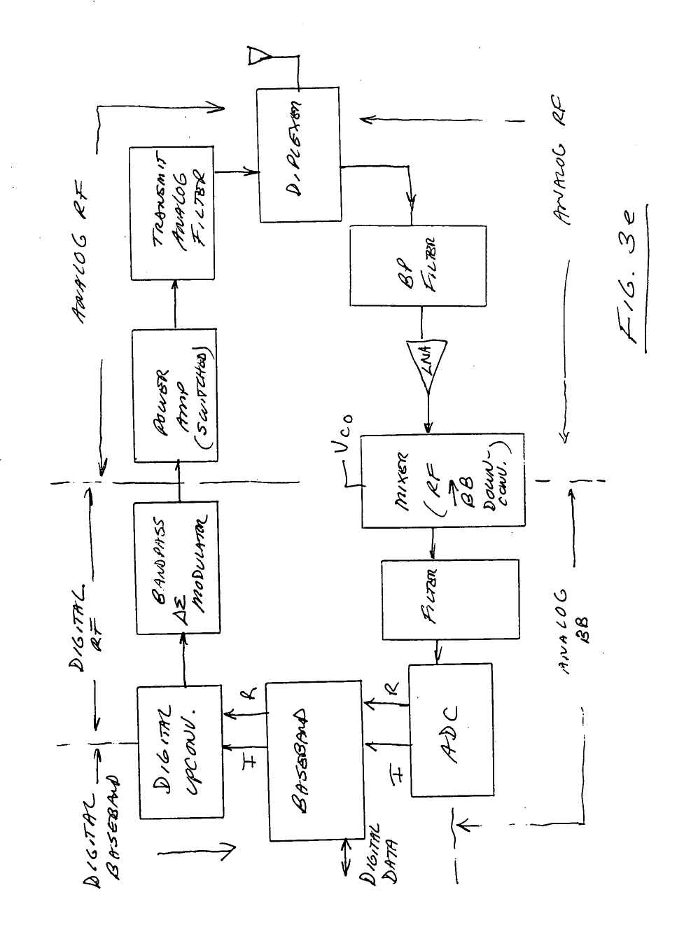

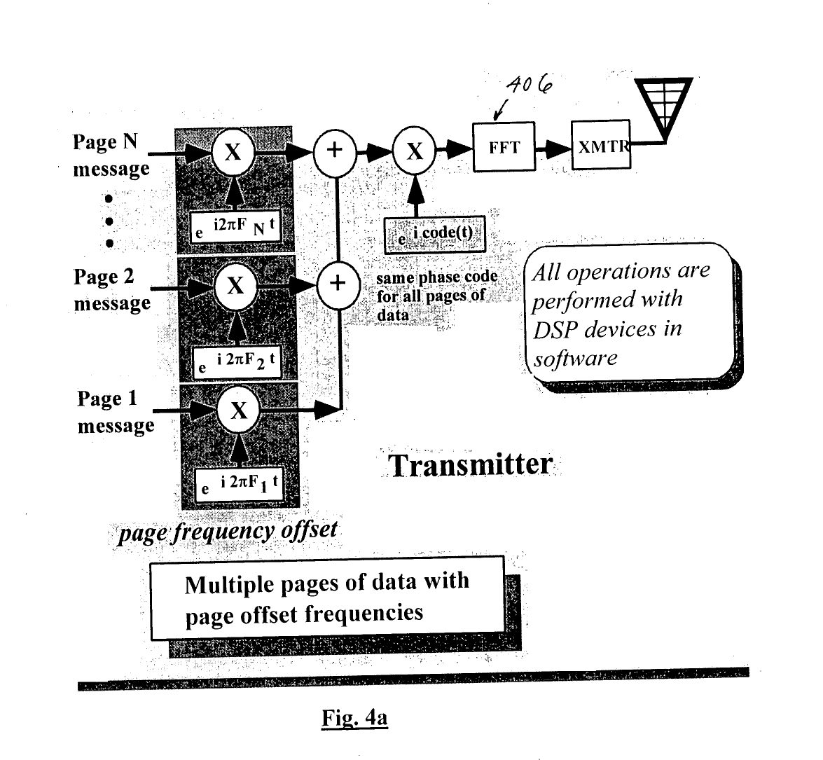

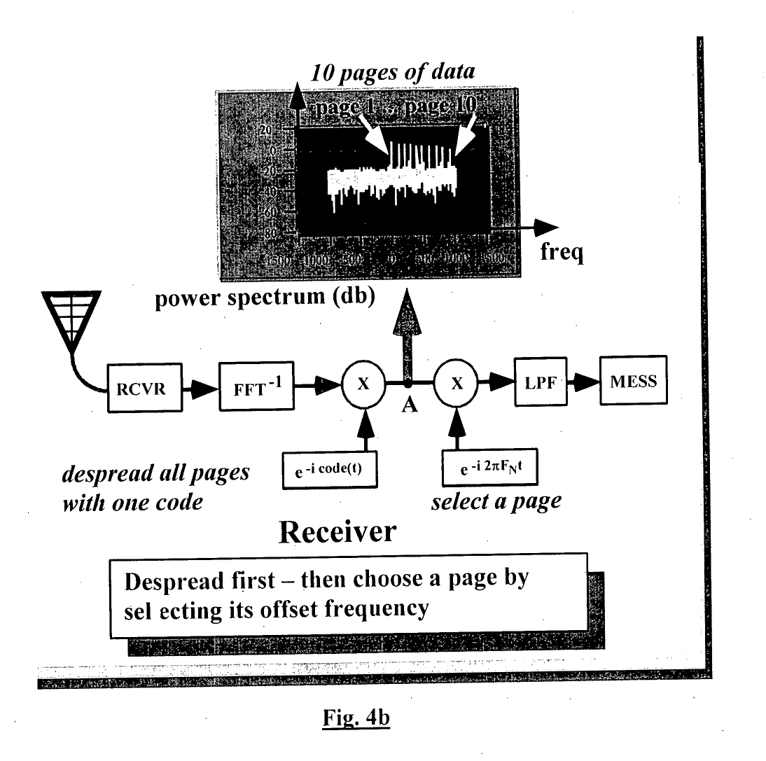

In another exemplary embodiment of the present invention (FIGS. 3a and 3b), a group of users of the communication system (which may comprise all or a subset of the total number of users of the system) are provided the same phase or scrambling code, but different baseband frequency offsets so that the narrow base-band spectrums of all the users are at least substantially orthogonal (non-overlapping). These offsets may comprise a predetermined set of frequencies (large enough to separate the basebands of the individual users, e.g. 10 kHz separations for voice, 10 MHz separations for video, etc.), or may be made deterministic on one or more other parameters (such as the selected “center” frequency, etc.). This approach is advantageously more efficient on the use of available spread band width and limited available codes, and further avoids problems of “friendly code jamming”, i.e., when all users are communicating simultaneously. In other words, the spread signals of those users with which a given user is not communicating do not act as significant noise for the one user with which the given user is communicating. This is in contrast to traditional DSSS/CDMA systems, wherein greater channel utilization does induce some degree of degradation in signal quality. The prior art is roughly akin to multiple individuals having separate conversations in respective different languages in a small room; each additional conversation, while in a different language, tends to increase the background “din” in the room, thereby degrading the quality of all other conversations within earshot. In contrast, the frequency offset approach of the present embodiment avoids such increased background din by effectively separating the different conversations sufficiently so that each set of conversationalists cannot hear the others.

In addition to reducing cross-degradation, this approach advantageously maintains (to a limit) constant processing gain for each additional user as for a single user transmitting alone.

As another embodiment of the invention, each different user's data structures (e.g., protocol packets, frames, etc.) can contain a binary or other prefix identifying that user unambiguously. Both the frequency offset and frame/packet prefix provide redundant identification of the user in the event offset frequencies change in transmission by delays.

The foregoing principles are illustrated in the exemplary configuration of FIGS. 3a and 3b (transmitter and receiver, respectively) for 10 simultaneous users, although it will be recognized that more or less users may exist consistent with the invention. As shown in FIG. 3a, the transmission process 300 generally comprises first encoding the user's message data using the same spreading code 302, then assigning a frequency offset to each 304. Specifically, when a user transmits a signal, a single modulator simultaneously converts the signal into a modulated signal using a common phase code q(t) and a respective frequency offset (F₁, F₂, . . . F_{N}). In one embodiment, bi-phase shift keying (BPSK) modulation is used.

It will be recognized that other digital modulator techniques may also be used, including but not limited to other phase shift keying (PSK) techniques, amplitude shift keying (ASK), frequency shift keying, continuous phase modulation (CPM), and “hybrids”. Other PSK techniques include but are limited to quadrature phase shift keying (QPSK), π/4-shifted QPSK, and differential quadrature phase shift keying (DQPSK). ASK techniques include but are not limited to quadrature amplitude modulation (QAM) and n-state quadrature amplitude modulation (nQAM, where n may equal different number of constellation values such as 64). CPM techniques include but are not limited to minimum shift keying (MSK) and Gaussian minimum shift keying (GMSK). Hybrid modulation techniques include but are not limited to vestigial side band (VSB). Likewise, quadrature phase shift keying (QPSK) can also be used to combine the real and imaginary parts of the complex holographic signal into one real signal for transmission over the air channel.

The signals of varying frequency offset are then fast Fourier transformed (FFT) 306, although other transformation techniques may be used (such as the Cosine transform described in greater detail subsequently herein). If digital-to-analog conversion is necessary, the signal will then be converted using a software or hardware DAC (see, e.g., the exemplary architectures of FIGS. 3c-3e). The signal is then transmitted using a transmitter 308, with FHSS spreading as previously described applied if desired. In the illustrated embodiment, a radio-frequency transmitter is utilized. However, as described below in greater detail, other transmitters may be used including, but not limited to, microwave (radar), sonar, and matter wave transmitters.

The illustrated RF transmitter may be of any type, including a heterodyne or super-heterodyne of the type well known in the art, direct conversion architecture (such as for example that described in WIPO Publication No W003077489 (PCT/US03/06527) entitled “RESONANT POWER CONVERTER FOR RADIO FREQUENCY TRANSMISSION AND METHOD” to Norsworthy, et al filed Mar. 4, 2003, and its counterpart U.S. Patent Application Publication No. 20040037363 published Feb. 26, 2004 of the same title filed Mar. 4, 2003, both incorporated herein by reference in their entirety, or even a simplified UWB architecture, the latter obviating any up-conversion, IF, and even power amplifier in certain circumstances. FIGS. 3c-3e show various exemplary transmitter architectures useful with the present invention, although others may be used as well. Herein lies a significant advantage of the present invention; i.e., significant independence of the holographic signal generation process from the transmitter architecture (and conversely for the receiver architecture).

Once transmitted, the receiver (FIG. 3b) receives the signal and the signal is converted from analog to digital using an analog-digital converter (A/D converter) if necessary. Hardware, firmware, or software, or any combination thereof, are used to inverse fast Fourier transform (FFT⁻¹) the signal 316. The receiver system de-spreads the signal before determining the intended user target by selecting the user's offset frequency. The signal is then low pass filtered and demodulated to extract the carrier from the data. As shown in FIG. 3b, all users have their transmissions simultaneously “de-spread” by one code, and low pass filters 320 in the receiver isolate each user from the others. Additional processing units in the receiver can allow the simultaneous reception of all users.

Although the assignment of different frequency bands for actual transmission (e.g., FDMA) is a known broadcast and communications technology, it has always been applied in the prior art to the actual transmitted waveforms. In the holographic technology of the present embodiment, however, the offset frequency bands are assigned in the base-band signal before code scrambling. The transmitted holographic waveform still comprises the same spread (and hopped, if desired) band as in prior embodiments; the aforementioned offset bands do not appear in the transmissions, thereby increasing the covertness of the transmissions. Likewise, the offset bands do not appear in the receiver after the inverse FFT until the transformed signal is first code de-spread. Accordingly, this embodiment of the communication system is well suited for military special operations forces and other small group communications (e.g., flights of related aircraft) where a limited number of users require highly covert communications.

It will also be recognized that the Fourier or other transforms used in conjunction with the invention can be performed on blocks of a fixed or variable size. For example, in one embodiment, a power of 2 is used as the basis for the transform. Alternatively, another embodiment varies the block size according to a variation scheme. One exemplary variation scheme comprises in effect randomizing the transform block size (such as between two or more selected powers of 2) via a pseudo-noise (pn) or other pseudo-randomized/randomized code. This latter approach advantageously increases the covertness and resistance to eavesdropping of the invention, since the constantly changing block size (i) further eliminates any “beats” or other easily-identified patterns within the holographic signal; and (ii) randomizes the FFT parameters such that even if one knows that a Fourier transform is being used to construct the signal, they will have extreme difficulty obtaining any useful information from the inverse-transformed signal due to the unpredictable transform parameters used within the transmitter. The block size can be modulated according to a pattern as well (e.g., block size “X” is a data “0”, and block size “Y” is a data “1” in a simple example), thereby in effect coding information therein. Such technique may be useful, for example, in training a receiver for subsequent reception; i.e., transmitting a data sequence via the block size modulation which uniquely identifies one of a plurality of available pn sequences to be used by both receiver and transmitter in varying block size as previously described, or which is used as a seed for a hopping algorithm.

Additionally, the offset frequencies assigned to multiple users need not be a fixed collection, but can be changed on a frame-by-frame or other basis if desired according to a pre-determined code pattern such as those previously described. This technique advantageously further randomizes the transmitted signals and minimizes the production of recognizable beats in the transmitted holographic signals. It also permits better identification of the individual users in the receiver in the presence of unknown delays between transmitter and receiver caused by signal transit time and the presence of multi-path signals. For example, were a fixed set of offsets assigned to a plurality of users, the presence of multiple propagation paths could potentially result in degradation of the signal associated with one or more users. In contrast, by varying the frequency offset assigned to those users, the effect of a given set of multi-path signals would vary as a function of the offset frequency, thereby limiting the period during which that particular effect would occur. Stated differently, each new offset can produce at least some variation in multi-path environment.

In yet another embodiment, offset frequencies are assigned to each user of the same scrambling code, in the ratios of prime numbers (i.e., those which are only divisible by themselves and one, including 1, 3, 5, 7, 11, . . . n). This technique helps minimize any recognizable beat patterns in the transmitted waveforms. Similarly, other “low observable” offset assignment schemes may be utilized, such as random or pseudo-random assignment via an algorithm as described above with respect to spectral hopping band assignment (FHSS), or yet other well known approaches. As yet another alternative, an adaptive approach can be used, wherein frequency offset assignments are made according to evaluations of channel noise, multipath, interference, jamming or the like. In this way, the system can intelligently and dynamically allocate frequency offsets to users in order to optimize channel quality, covertness, or some other desired metric.

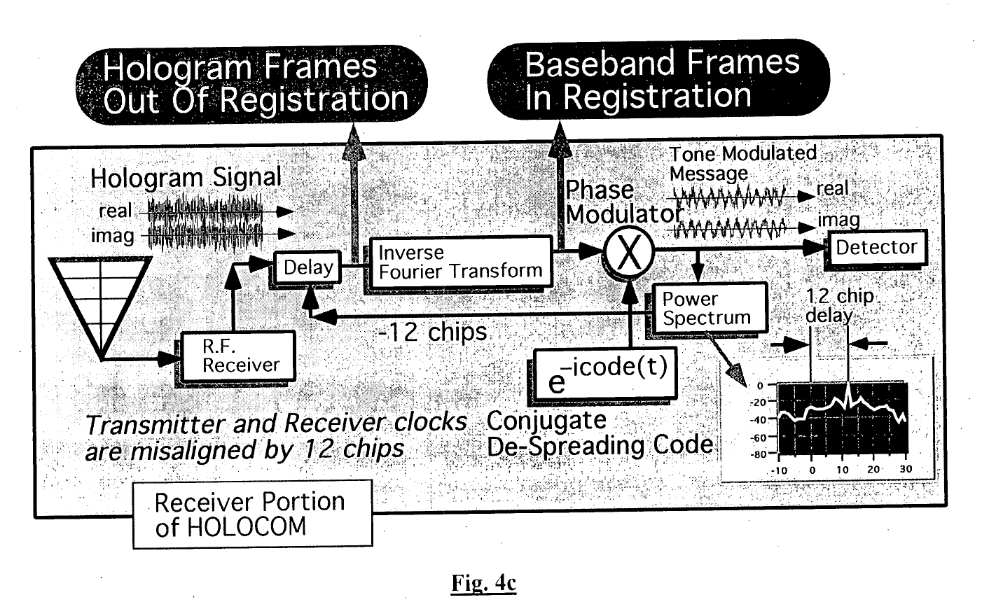

It will be further recognized that the aforementioned feature of assigning the same scrambling code to multiple users, and using offset frequencies to separate them at the receiver, can also be adapted to effect high bandwidth communications of large amounts of data by a few users or one user. In one exemplary embodiment (FIGS. 4a and 4b), the information is represented by a plurality of “frames” or packets of waveform data being transmitted simultaneously. Note also that such frames may also comprise logical content streams, such as an MPEG video stream. Each frame has the same scrambling code but a different offset frequency. In one exemplary transmission-processing scheme, all of the different frames are added together to form a single composite “super frame” before the Fourier Transform operation (FFT) 406 of FIG. 4a is conducted.

Each page or frequency offset of data can also be utilized on a logical channel basis, akin to the well known virtual path/virtual channel (VPI/NVCI) approach used in asynchronous transfer mode (ATM) systems of the networking arts. For example, in one embodiment, allocation of a given packet across different frequency offsets can be controlled using a higher layer allocation algorithm. In this regard, each of the different frequency offsets comprise effectively a different narrowband carrier for the data. The packets or other data structures are constructed using a packetization or framing protocol to contain identifiers (such as stream or user IDs or other such mechanisms) that allow reconstitution of the logical stream of packets at the receiver; i.e., after inverse transformation and de-spread into multiple offset frequencies in the baseband.

In yet another embodiment, a multitude of users, each with a multitude of frames of data, use the same scrambling codes, but offset frequencies different for each user, and different for each of the information frames, are provided. Once again, all the offset frequencies are chosen to eliminate beat or otherwise recognizable patterns in the transmitted signals (through, e.g., use of prime numbers or other comparable mechanisms previously described herein).

The foregoing approach may also be applied dynamically by the system. For example, where communication between multiple (sets of) users is required, each user can be allocated a frequency offset. However, where one or more users wish to transmit larger amounts of data, available frequency offsets can in effect be traded for bandwidth, with one or more users having multiple offsets assigned to them. Such users can then continue voice communications if desired, as well as using other assigned offsets for data transmission, up to the available communications bandwidth of the system.

Such “data page offset” approach may also be employed for “bursty” communications, for example where the user wishes to transmit a large amount of information in a short period of time. This feature may be useful to maintain covertness (i.e., shorter temporal duration of transmission generally equates to greater reduction in probability of intercept), or to maintain continuity of communications with respect to geographic or structural hazards such as large buildings or tunnels. Also, use of delayed bursty communications reduces the signal processing threshold requirements of the communications device, since the signal processing can operate more slowly and in effect process “batches” of data for later transmission, unlike a continuous streaming environment where temporal continuity is required. This reduction of signal processing requirements also necessarily produces a savings in power consumption and/or cost, since a lower-performance and ostensibly smaller and cheaper device can be used in conjunction with bursty communications modes as opposed to the use of the higher performance device whose capacity is only needed perhaps in limited circumstances (such as continuous streaming or very high rate data).

It is to be recognized that in all of the above described frequency offset techniques for both multiple users and multiple pages of data per user, processing gain can remain the same as for a single user and is determined solely by the ratio of total spread bandwidth to the bandwidth of a single page of data. It is also to be recognized that the data rate for each page of data and user can be different and in fact dynamically changed from frame to frame.

Defeating Interceptors by Time Dithering

The transmitted holographic waveforms associated with the exemplary embodiment of the '480 patent solution generally have the appearance of wide-band, zero-mean, stationary Gaussian noise. They appear to be natural background or thermal noise. There is very little content contained in these waveforms that an interceptor of the signal can recognize as human made other than finite power. However, the '480 patent solution does in one embodiment make use of signals sampled at a definite or predictable chip-clock rate. A determined and sophisticated interceptor might make use of correlation receivers of the type known in the communications arts that seek to identify a chip-clock signature within a spread holographic spectrum, thereby detecting the presence of the transmission with some reliability (albeit perhaps not the content of what is being transmitted). In many situations, such as for example the search and rescue of downed aviators during wartime, or the operations of special forces, even the detection of communications aside from their content can provide a basis for hostile forces to DF or locate the transmitter, or at least be alerted to its presence.

For a more covert or stealthy holographic signal, one exemplary embodiment of the present invention dithers the epoch of the chip clock by, e.g., a fraction of the base chip rate (or some other parameter such as a prime number-based scheme). This dithering procedure can significantly reduce the efficiency of a correlation receiver in detecting the presence of the holographic signal, in effect taking away any regular or predictable “man-made” component of the transmitted signal that may exist. The dithering of the chip rate can be made totally deterministic if desired, and dependent upon sequences of random or pseudo-random numbers known to both transmitter and receiver of the holographic signals (such as by using the aforementioned pseudo-random algorithms). Numerous commercially available devices can be used to dither the clock, such devices being readily implemented by those of ordinary skill given the present disclosure.

In another embodiment, the sequence can be derived from the base scrambling codes previously described, so that only one code sequence need be used (thereby simplifying the required processing by the baseband or other digital domain processor). The receiver then “un-dithers” the received signal, and recovers the base-band messages with higher fidelity.

Use of Real Data and Real Transforms

Complex waveforms (two components, real and imaginary) generally require specifically adapted hardware and software, thereby increasing the cost and complexity of any holographic solution. Accordingly, in one exemplary embodiment of the invention, all “real” signals (i.e., having no complex or imaginary component) are used. This is advantageously less expensive and less complex in hardware and software implementation. The two approaches can also be mixed as desired, with adaptive or “intelligent” transition from complex to all-real domains and vice-versa.

For example, since less computationally intensive hardware (and software) is required for the all-real processing, the baseband processor (or portions thereof, such as the memory subsystems and/or portions of the instruction pipeline) can be shut down or put into “sleep mode” to conserve electrical power. Consider the multi-core processor array such as those described subsequently herein; as the complexity of the processing task is reduced; e.g., by transitioning from a real/complex phase coding and transform to an all-real process, portions of certain cores or even complete cores can be put to sleep within a few processing cycles using any number of well-known techniques such as a “SLEEP” instruction. See, e.g., United States Patent Application Publication No. 20030070013 to Hansson published Apr. 10, 2003 and entitled “Method and apparatus for reducing power consumption in a digital processor” incorporated herein by reference in its entirety, for exemplary methods of controlling the power consumption in a digital processor.

Fourier Transforms (FFTs) represent one time domain-to-frequency domain conversion technology useful with the present invention, although other kinds of transformations that also preserve the convolution feature of the FFT may be used (including without limitation Hadamard transforms and number theoretic transforms). Some of these other transformations can be used entirely in the real data domain, such as the Cosine transformation. The all-real FFT and Cosine transformation not only take a real input, but also produce a real output waveform for transmission. Each is generally faster than the complex Fourier Transform, and cheaper to implement in hardware/software. However, as is well known, the complex Fourier transform can also be used to transform two real signals simultaneously if necessary. For example, the enhanced FFT processing methods and apparatus disclosed in pending United States Patent Application No. 20020194236A1 to Morris published Dec. 19, 2002 and entitled “Data processor with enhanced instruction execution and method”, which is incorporated herein by reference in its entirety, allow even an embedded RISC device to perform the required FFT operations at very high speed.

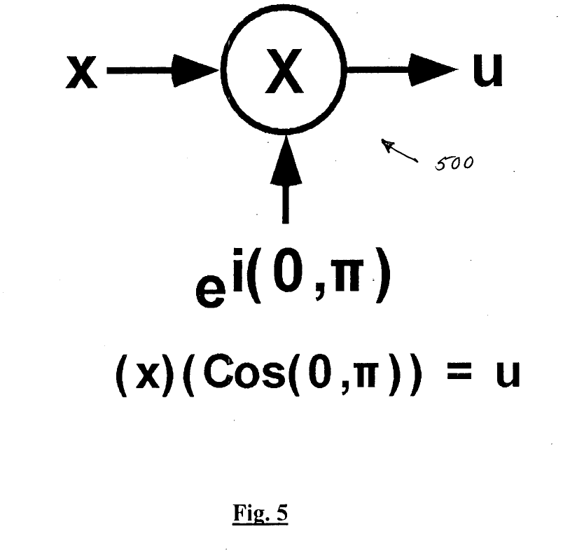

One exemplary phase code modulator embodiment described in the '480 patent produces complex base-band signals by incorporating all angles from −π to +π. However, by operating the modulator with just two angles, e.g., 0 and π, chosen randomly, the resulting phase codes are real consisting of 1s and −1s (see FIG. 5 herein). The phase code modulator 500 then operates in effect as a “direct sequencer”. Specifically, if the DC reference signal is removed, and only the PSK signal retained, an all-real base-band signal is produced for the transformer operation, comparable to a direct sequencer. The tradeoff in implementing this approach is the loss of the DC spectrum spike used in the exemplary '480 patent receiver to locate frequency-offset signals after code de-spreading.

Accordingly, in one exemplary embodiment, the receiver of the present invention is configured to locate the spectral peaks of Sin(x)/x type distributions from real PSK waveforms. This is accomplished via a software algorithm running on the processor (e.g., DSP or array processor) of the receiver, although other approaches (including custom ASICs or hardware logic) adapted to determine the spectral peaks may be used. Such peak-detecting algorithms are well known in the signal processing arts, and accordingly not described further herein.

In another exemplary phase code modulator embodiment, a portion (e.g., 10%-50%) of each PSK signal waveform is replaced by a DC reference. The advantage of this approach is that the transformer input base-band is still real in nature (and hence can make use of the attendant reductions in processing overhead previously discussed), but a spectral spike is observed at the receiver to help locate frequency offset signals. The tradeoff in implementing this approach is a data capacity reduction.

Doubling Data Rates

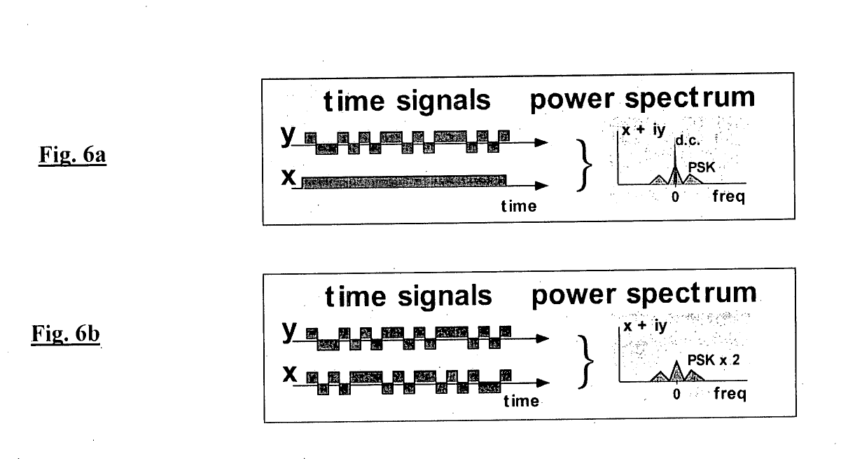

In yet another embodiment of the invention, an improved method of referencing is utilized. Specifically, the use of one input channel as a reference signal (used to encode a constant value signal that produces a sharp frequency spectrum spike that is easy to recognize, as shown in FIG. 6a) is obviated in favor of a technique whereby the data rate of the communications is significantly increased (e.g., effectively doubled in a two-channel system). In the exemplary embodiment, the former reference channel is used for actual PSK type data, similar to the other non-reference channel(s). Rather than generating a spectrum spike for the receiver to locate, a broader Sin(x)/x or comparable type distribution is generated, from which the location of the peak can be made as is done from the original “spike” spectrum (see FIG. 6b). Hence, enhanced data throughput is achieved.

In still another embodiment of the invention, a hybrid version of the two approaches is used, with a portion of each input channel previously used as a reference signal (50%-75% for example) being filled with data. A lower amplitude spectral spike is still produced for referencing, but now more data is transmitted as compared to devoting one entire channel to spike generation.

Measuring Distances and Other Dynamic Variables from the Delayed Holographic Signal

Delay present in the received holographic signal is primarily due to the finite transit time T of the holographic signal from the transmitter to the receiver. Thus, if T is measured to be 500 ns, the distance from transmitter to receiver is approximately 500 feet (for an electromagnetic wave propagating at approximately 3E08 m/s). Spectral estimation methods well known in the art allow measurement of the frequency offset of the base-band signal in the receiver to an accuracy that permits determination of T, with an error on the order of 50 ns or less. Fourier analysis of the type well known in the art is used to directly relate the time shift (delay) in the holographic signal to its de-spread spectral offset frequency. Accordingly, the present invention provides ability to use the received signal to estimate the distance to the transmitter. In the foregoing example of measurement accuracy to 50 ns, the range or distance precision is on the order of 50 ft (15 m). At 10 ns accuracy, range resolution is approximately 10 ft (3 m). Also, with two separated receivers, the transmitter can rapidly be located (in two dimensions) by well known triangulation means.

In one exemplary embodiment, the receiver is configured with apparatus (e.g., high speed logic or algorithms) adapted to analyze the power spectrum of the de-spread received signal in order to identify the presence of the DC spike or other artifact (such as Sin(x)/x distribution, or another type of mathematical distribution), and the offset present. See FIG. 4c for one exemplary receiver architecture. The offset is then correlated to the time delay, and distance determined via the propagation speed.

Once distance is measured to a transmitter, and a regular time series of distance measurements created, other dynamic parameters such as relative speed and acceleration of the transmitter or receiver with respect to one another can also be determined by finite approximations of various derivatives. For example, if R1 and R2 represent two successive distance calculations separated in time by dt seconds, the relative speed between transmitter and receiver is approximated by (R1-R2)/dt.

Correcting Multipath Distortion

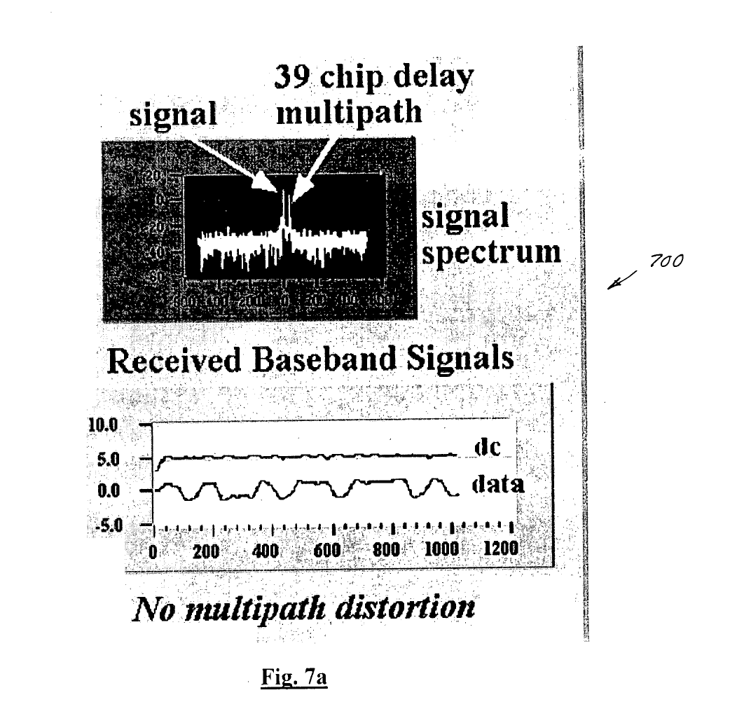

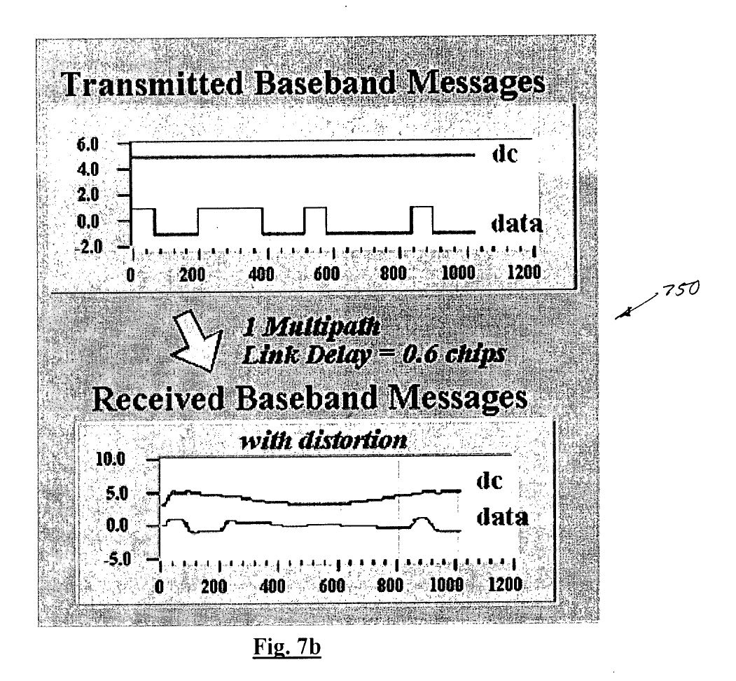

In another aspect of the invention, apparatus and methods for correcting for multi-path distortion are provided. FIGS. 7a and 7b illustrate one embodiment of a method 700, wherein filtration is used to isolate and remove the time-delayed multi-path signal. Advantageously, after the inverse Fourier transformation in the receiver, the multi-path signals are all in time registration, but have frequency offsets characteristic of their time delays in the air channel transit. This is a known property of the Fourier transform algorithm. An additional benefit of the invention is that all the multi-path signals can be simultaneously de-spread by a single code (inverse of original scrambling phase code). A spectral display of the baseband shows the individual power spectrums of each multi-path signal. Spectrums that do not overlap can be removed by e.g., band-pass filtering, such as by rejecting anything outside of a given window (corresponding to, e.g., the primary transmission mode). Alternatively, where the power spectrums of the various multi-path propagation modes have sufficient separation; they can be isolated and added together in the receiver after de-spreading to form a single power spectrum (or multiple groupings or subsets if desired). Accordingly, what would otherwise wasted radiated energy from the transmitter is at least partly recoverable at the receiver. Accordingly, under such conditions, the transmitter power that would otherwise be required without multi-path addition is reduced, thereby providing any number of benefits including extending transmitter battery longevity, reducing probability of intercept, reducing interference with other RF band equipment, etc.

When the multi-path delays are small and numerous, the aforementioned spectral bands overlap and cannot be separated by such simple filtering. The overlapping bands produce a reconstructed baseband interference that appears as signal fading. The disadvantage of current wireless technology is that multi-path signals not only can interfere with one another in the above-described fashion, but are not registered in time as well. This makes the multi-path fading more severe than for the holographic technology. To correct this overlap interference, the present invention can utilize any number of different approaches, including: (i) changing the transmission frequencies in order to change the multi-path environment and hence recovered baseband spectra, or (ii) simultaneously transmit baseband messages at multiple frequencies or frequency bands (multiplexing). Another solution that can be implemented is to use convolutional encoding alone or in conjunction with frequency shifting or frequency multiplexing to correct the errors introduced by the multi-path fading.

Another solution to minimize or negate multi-path distortion is to change the base-band modulation, and use incoherent modulus (absolute value) detection. Instead of using coherent, antipodal (+/−1) PSK modulation, unipolar (0/1) signals are used to represent a “zero” and a “one” bit. For example, a multi-path consisting of the direct mode and one reflection is primarily distorted by 180 degree phase reversals. With antipodal PSK, the reversals cause O's to become l's and l's to become O's. With (0/1) unipolar signals and modulus detection, such phase reversals cause no bit errors. The modulus value of such a signal will be a 0 or 1 according to the data bit, while with PSK, the modulus is always 1 regardless of the bits.

Still another solution to minimize or negate multi-path distortion is to measure the distorted signal on a known transmitted signal and utilize an inverse filter for the calculated distortion. This is accomplished as part of the receiver signal registration process using known constant amplitude reference signals, which are part of each page of data.

It will also be readily appreciated that the foregoing techniques may be applied in concert, and/or dynamically switched in and out of the receiver under varying operational conditions. For example, in one embodiment, the receiver is configured, using high speed filtration hardware and supporting algorithms running on the receiver baseband processor or a co-processor, to detect the degree of separation between multi-path modes present in the baseband (i.e., the degree of overlap between the different individual modes) in order to dynamically impose selective filtration and/or addition of the signals as previously described. A threshold criterion may be imposed, such that when the criterion (or multiple criteria) is met, filtration and/or addition is used to “clean up” the baseband power spectra into a unitary spectrum. Regarding signal addition, this approach can also employ AGC reverse channel communications (described below) in order to control or recommend changes in transmitter power. As such mode addition is successfully performed in the receiver, less transmitter power is ostensibly required.

Similarly, when the multi-path modes are highly overlapping, distortion measurements of the baseband reference signals can be switched in to help isolate the primary transmission mode, and/or unipolar modulation switched in to aid in cleaning up the baseband power spectrum.

AGC

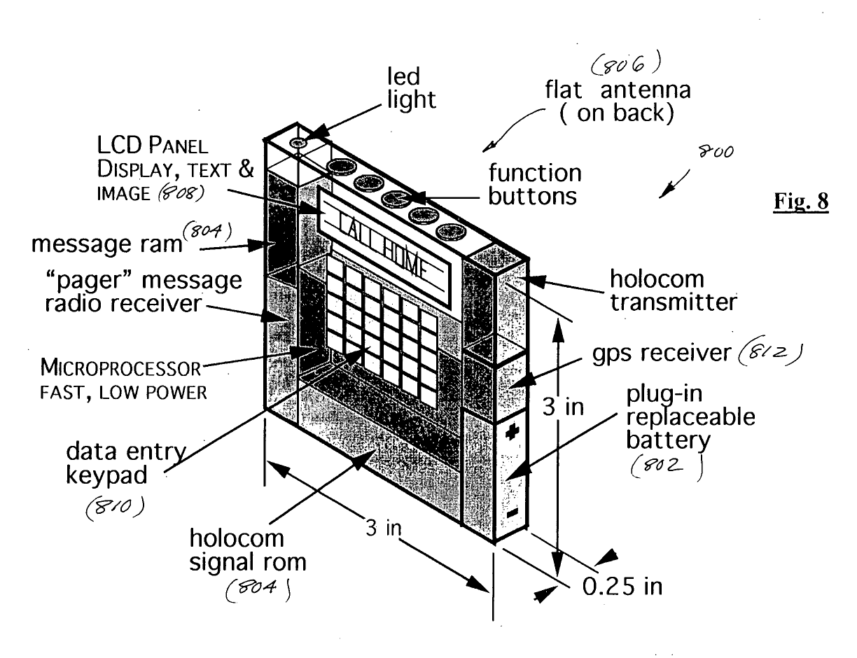

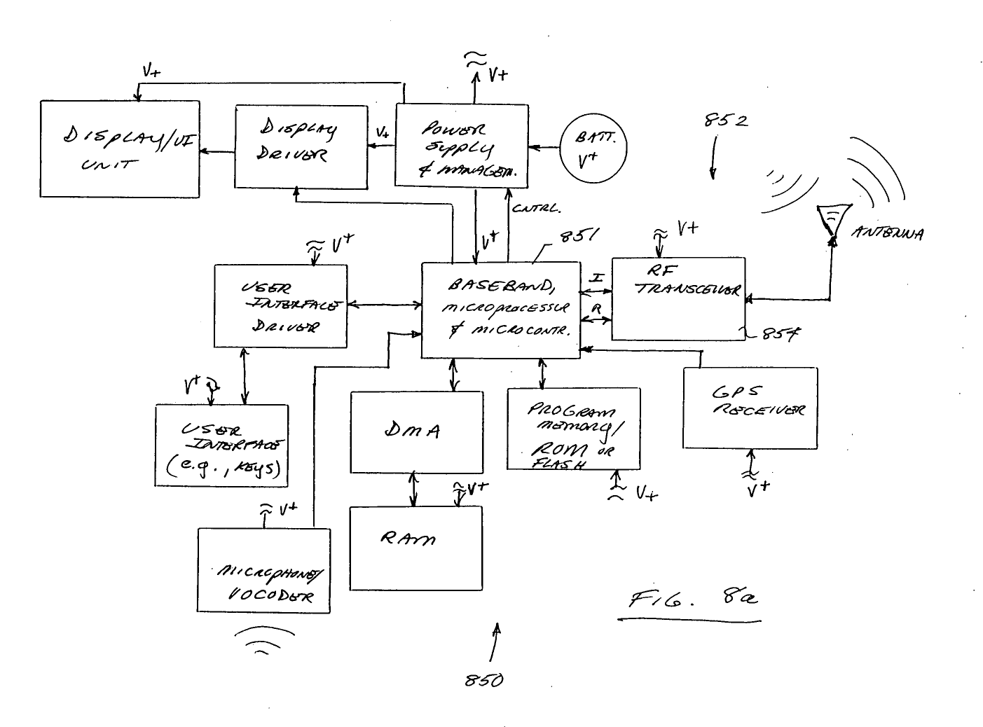

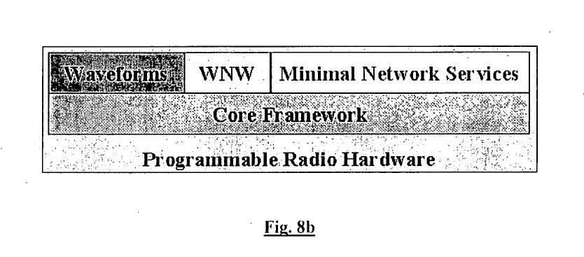

In another aspect of the invention, holographic transceiver devices according to the present invention (see, e.g., the device of FIG. 8) can optionally be equipped with automatic gain control (AGC) of the type generally known in the RF arts in order to control the power of emissions from the device's transmitter. In the context of a prior art CDMA system, AGC is used to, inter alia, control the power from the mobile transmitter, so as ideally to keep the transmitter at an optimal power for the prevailing distance from the base station, environmental conditions, etc. In this fashion, both mobile device power is conserved, and one mobile unit does not “flood” or wash out other lower-power or signal strength transmitters.

In the context of the present invention, such AGC can be used for any number of different reasons, including maintaining a high degree of covertness. Obviously, greater transmitter power levels reduce covertness under most every conceivable circumstance, and hence it is desired to maintain transmitter gain at a level just sufficient to maintain suitable error rates/SNR over the air interface. Generally speaking, this can be determined (a) independently; i.e., by measuring the ambient “noise” environment and deciding, such as based on a priori or a posteriori information, on an appropriate gain at which to transmit; (b) in concert with the receiver; i.e., awaiting feedback or AGC instructions transmitted from the receiver or another entity such as a common transmitter; or (c) some combination of (a) and (b). Various channel quality metrics can be used, such as BER for known message content, use of CRC and the like in order to determine the level of degradation of the channel at a given transmitter gain setting (or other setting, such as code-spread bandwidth or the like). However, with the inherent redundancy of the holographic waveforms, even significant losses in the time and/or frequency domain can be tolerated depending on a variety of design and operation factors; hence, AGC becomes less of an issue of channel error and more one of covertness/LPI.

A simple form of “AGC” contemplated by the present invention is merely an acknowledgement from the receiver; for example where a one-way communication is initiated (such as a preformatted message from the device 800 of FIG. 8). The receiver can, upon sufficient receipt and decoding of the message, send back an ACK message which terminates further transmissions. Alternatively, if no ACK is received from the receiver, the message transmitter may then automatically increment the gain and/or vary other parameters of the waveform and retransmit the message, hopefully receiving an ACK. This process can proceed until an ACK is received, or alternatively until a preset gain threshold is reached (corresponding to e.g., a EIRP that would increase probability of intercept beyond a safe value), at which point alternate communication channels and/or parameters may be invoked. Similarly, a NACK may be used by the distant receiver to identify those situations where the message was incompletely received, the user's authentication failed, or other such conditions exist. The ACK or NACK may also be used to selectively disable the device, as described in greater detail below with respect to the exemplary device of FIG. 8.

Miniature Holographic Technology

Today's high speed (multi-Gflops processing speed), low power consumption, digital processors and SoC technology allow an entire holographic transmitter and receiver to be integrated and constructed in a very small form factor. Provided herein are exemplary embodiments of such miniaturized technology employing some or all of the foregoing improvements therein, although it will be recognized that myriad other types and configurations may be used consistent with the present invention.

Referring now to FIGS. 8 and 8a, one exemplary embodiment of a miniature transmitter/receiver is disclosed. The form factor of the illustrated device 800 is approximately 3 inches by 3 inches by 1/4 inch, including batteries 802, memory 804, antenna 806, display 808, etc., although it will be appreciated that this form factor may be varied as desired. The device 800 comprises a miniature holographic communication system, including optional keypad LCD or capacitive “touch” screen 810, that can be worn by individuals and easily attached to equipment and vehicles and used for dog tags, identification, geographical tracking, always-ready secure and covert communications search and rescue radios, and “identify, friend or foe” (IFF) communication devices. Such devices can also be disguised as other devices for covertness or surreptitious tracking of people or equipment. Devices such as that of FIG. 8 are especially useful in anti-terrorist activities and drug smuggling interdiction, where the target terrorists or drug smugglers frequently possess communications intercept equipment or other means capable of “tipping them off” to the presence or approach of military or law enforcement personnel.

FIG. 8a is a functional block diagram illustrating an exemplary hardware architecture 850 for the device 800. As will be recognized, this architecture may use any manner of RF interface 852, since the holographically encoded signals previously described herein are substantially independent of the bearer medium. For example, a traditional heterodyne or super-heterodyne approach may be used for the transceiver 854, or alternatively a direct conversion (e.g., delta-sigma modulator with noise shaping coder) may be used. An ultrawideband transceiver is highly desirable based on its comparative simplicity and low radiated power (thereby increasing battery longevity or alternatively allowing reduction in battery size and capacity); however, such UWB systems are physically limited in range as compared to heterodyned or other approaches due largely to the propagation mechanics of high-frequency UWB signals. Co-pending and co-owned U.S. provisional application Ser. No. 60/529,152 filed Dec. 11, 2003 and entitled “WIDEBAND HOLOGRAPHIC COMMUNICATIONS APPARATUS AND METHODS” and the progeny thereof, all previously incorporated herein by reference in their entirety, describe exemplary UWB transmitter and receiver apparatus that may be used consistent with the present invention, although other approaches may also be used with success.

Furthermore, consistent with space and power consumption limitations in the device, two or more transceiver paradigms or air interfaces may be used consistent with the invention. For example, the device 850 may include a UWB and a heterodyne-based transceiver, and switch between them selectively, such as based on range to the receiver, desired covertness level, presence of narrowband jammers, etc. This switching or selective utilization may also be controlled via a software/firmware process, such as the SD/CR approach described elsewhere herein.

The exemplary device 850 of FIG. 8a further includes a baseband processor (which may also integrate microprocessor and microcontroller functionality) 851, program and data memory devices 856, a direct memory access (DMA) device 858, GPS receiver circuit 860, display unit 862 and driver 864, user interface (e.g., touch pad or keypad) 870 and driver 872, and power supply 874. The construction and operation of each of these devices is well known to those of ordinary skill in the electronics arts, and accordingly are not described further herein. It will also be recognized that the architecture of FIG. 8a is merely one possible arrangement that can be sued with the device 800 of FIG. 8; myriad other features and configurations can also be utilized.

The device 800 of FIG. 8 is also optionally provided with the additional capabilities of sending out pre-formatted or standardized messages such as for help, extraction or notification of injury, as well as “off-air” recordings of any nature and content. The holographic waveforms encoding the messages are pre-calculated and stored in memory (e.g., RAM of the device), and transmitted instantly by, e.g., the pressing of a single button on the device. The transmissions can also be automatically instigated, such as e.g., upon (i) receipt of a properly encoded or authenticated holographic waveform from an external source (or other communication), (ii) a certain period of time elapsing; (iii) the lack of any detected RF waveforms received by the transceiver of the device 800, (iv) achieving a predetermined location or set of coordinates (for example as determined by the GPS receiver); (v) receipt of a biometric signal from the parent user (or loss thereof, such as a “heartbeat” monitor); (vi) exceeding a given ambient temperature or other environmental parameter; (vii) detection of an antigen or chemical agent via an external or integrated detection device; (viii) receipt of a signal from a weapon indicating malfunction, exhaustion of ammo supply, etc.; (ix) proximity to another holographic transceiver; or (x) experiencing g-forces in excess of a given threshold (such as may be measured by an electronic accelerometer). This off-air recording and separate transmission can significantly reduce the workload and data rate capacities of the device processor, as well as lower costs and power consumptions requirements.

In one embodiment, the various holographic communications are performed on a fully integrated low-voltage “system on a chip” (SoC) application specific integrated circuit (ASIC) of the type generally known in the semiconductor fabrication arts (. The SoC ASIC incorporates, inter alia, a digital processor core, embedded program and data random access memories, radio frequency (RF) transceiver circuitry, modulator, analog-to-digital converter (ADC), and analog interface circuitry. Flash memory may also be used to allow rapid reprogramming and download of new code, as is well known in the embedded device arts.

In one exemplary variant, the ASIC comprises a super-low gate count ASIC comprising one or more embedded RISC processors, such as the A600 or A700 mixed 16-/32-bit ISA processor cores manufactured by ARC International of San Jose, Calif. These devices have excellent high-speed processing capability, while maintaining extremely low gate count (and hence power consumption). These devices are also readily integrated with other peripherals and device 800 components on a single die, thereby reducing size and power consumption to an absolute minimum. Additionally, multiple RISC cores can be used in an array for more demanding processing requirements (such as where a “continuous” streaming mode is required versus bursty communications); the additional RISC cores in the array can be brought on selectively as a function of required processing so as to minimize power consumption. Advantageously, the exemplary FFTs (and inverse FFTs) of the holographic signal processing described elsewhere herein are highly scalable in silicon (e.g., by powers of 2); hence, a given “large” FFT such as a 16K pt. FFT can be broken into multiple sub-operations dynamically allocated to different cores in the array, thereby making maximum use of the parallel architecture of the ASIC.

In another exemplary embodiment, the Motorola MRC6011 Reconfigurable Compute Fabric (RCF) is used as the basis of the device processor. The 24 Giga-MAC MRC6011 is well suited for MIPS-intensive, repetitive tasks (such as transform processing), and offers a resource-efficient solution for computationally intensive applications such as the holographic encoding described herein. The MRC6011 is highly programmable and advantageously provides system-level flexibility and scalability of a programmable DSP while also providing appreciable benefits in terms of cost, power consumption, and processing capability as compared to traditional ASIC-based approaches. Specifically, the MRC6011 is capable of up to 24 Giga-MACS (16-bit) at 250 MHz, and up to 48 4-bit Giga complex correlations (CC) per second at 250 MHz (0.13 micron process). It uses a scalable architecture of three RCF modules having 16 reconfigurable processing units that is rapidly reconfigured under software control. It can also process block interleaved Multiplexed Data Input (MDI) data, and has power consumption typically less than 3 W.

Additionally, the processor core(s) (and in fact the entire SoC device) optionally includes one or more processor “sleep” modes of the type well known in the digital processor arts (see, e.g., Hansson previously incorporated herein), which allow portions of the core such as the pipeline and memory subsystems, and/or peripherals, to be shut down during periods of non-operation in order to further conserve power within the device. Such sleep modes can be instigated within very few cycles of the processor(s), thereby increasing efficiency. Gray coding of the type well known in the semiconductor arts can also be employed within the processor cores and/or other components of the device 800. By allowing only one bit to change at a given time, additional power that would be consumed within the IC is reduced, thereby making for more power-efficient (albeit slower) operation.

The miniature transceiver 800 may also contain a miniature GPS receiver 812 of the type well known in the art (which may be a discrete component, or configured in silicon), and be configured to include precise location data with covert transmission of messages or data, as well as providing other functions (such as display of current coordinates of the user, for auto-generation of messages as previously described, etc.). Alert messages, such as those asking the user to perform a specific action, or alerting them to the presence of nearby hostile forces, can be sent to a built-in “pager” receiver disposed within the device 800 from other assets such as satellites, overhead aircraft, nearby ships, etc. As previously discussed, the device's memory may also be sized and configured to contain preformatted messages (e.g., “Downed Aviator” or “Medevac” with attached location data, “Airstrike Request” with desired strike location(s), “Overhead Asset” tasking request with desired location(s), etc.) so that the operator need merely push an appropriate button to instigate the transmission. The memory may also be sized to capture a predetermined quantity of real-time video data generated by an optional CMOS or CCD camera device optionally included within the device 800 as described subsequently herein.

The device 800 may also be equipped with ranging and triangulation capabilities such as those previously described herein, in order to automatically determine the location of other holographically-equipped devices in proximity to the user. This may be useful where GPS positioning data is either not available or not reliable, such as underground or in a cave system or other such natural formation (or alternatively for space-based applications not serviced by the GPS constellation). In one variant of the device 800, the locations of such other users may be displayed on a TFT or LCD display referenced to, e.g., relative or absolute compass headings or some other frame of reference intuitive to the user. This data may also be bursted or streamed off-device to a third party such as a remote field commander.

The device 800 of FIG. 8 may also optionally include one or more authentication mechanisms which enhance the security of the device and prevent surreptitious use by third parties such as enemy captors. These authentication mechanisms can range from a simple password, to more sophisticated biometric techniques, to combinations of the foregoing. Specifically, since the device 800 may be carried by numerous members of the armed forces, security forces, etc., one design objective is to frustrate such surreptitious use and hence attempts by an enemy to “call for help” or otherwise draw friendly forces into a compromising position. Operational considerations include (i) the threat of torture; (ii) loss during normal or non-combat use by the owner; and (iii) retrieval from a deceased owner during combat. Hence, purely biometric approaches (such as a fingerprint) can conceivably be bypassed under torture or death of the owner. Similarly, those based solely on a user's knowledge can be “tortured out” of the user; accordingly purely discretionary approaches are not desirable.

Rather, various embodiments of the present invention utilize a mixture of different measures to help frustrate such surreptitious uses. In one embodiment, this mixture comprises a speaker identification algorithm (and microphone/audio codec) of the type known in the signal processing arts. See, e.g., U.S. Pat. No. 6,424,946 to Tritschler, et al. filed Jul. 23, 2002 and entitled “Methods and apparatus for unknown speaker labeling using concurrent speech recognition, segmentation, classification and clustering” assigned to IBM Corp. and incorporated herein by reference in its entirety.

This type of algorithm is to be distinguished from speech recognition (i.e., substantially speaker independent recognition of words or identification of languages or dialects), in that the present embodiment of the invention identifies particular patterns within the owner's voice samples to positively identify the speaker as the owner, largely irrespective of what the content of their speech is (in terms of linguistic constructs), although both speaker identification and speech recognition may advantageously be combined hereunder to produce even further security. Under such an embodiment, the speaker must both (i) be positively identified based on their stored voice print as the registered owner; and (ii) recite the proper content (e.g., a “challenge phrase” that only they would know). Any transmission, reception, or other operations of the device 800 would be locked until proper authentication is completed, and the device may even be permanently or semi-permanently disabled upon failure to authenticate (such as after two or three failed attempts).

This (semi) permanent disable feature may also be invoked automatically or manually by a user, and used to their advantage during capture by the enemy. For example, the owner may appear to comply with the captors, speaking a challenge phrase (but not necessarily the correct one) two or three times, thereby permanently disabling the device. The device 800 can even be programmed upon such disabling (such as via a routine stored in flash memory) to appear to transmit a signal, thereby deceiving the captors into thinking that the owner complied to the fullest and successfully initiated the device. As yet another alternative, the device 800 may be programmed under such circumstances to transmit a “potentially non-friendly” or equivalent message indicating to the receiver that the wrong challenge phrase was invoked, thereby alerting the receiver that the owner of the transmitter device 800 has likely been captured. This approach hence allows the owner a completely passive means of letting the receiver know that he/she has been captured and is still alive (since the voice identification validation must be successfully passed before the transmission can occur).

Similarly, specific sequences of messages or message content (or input commands) can be used to disable the device or alert the distant receiver of an attempt to surreptitiously use the device 800. For example, the owner may preprogram the device 800 to emit a certain sequence of preformatted messages which, if out of sequence or incomplete, may indicate unauthorized use. The captor or enemy attempting to use the device will not know what the sequence is, and hence a series of transmissions can occur, yet they will be readily identified at the receiver as not complying with the required protocol(s).

In another variant, the user is required to “periodically” reset the device; if reset is not accomplished, the device automatically disables itself. Here, the term “periodic” means any regular or non-regular series of events, including without limitation the elapsing of time, “counts” of certain events such as transmissions or receptions of messages, number of miles registered on an attached pedometer, etc.

In yet another variant, an external source is used to transmit a holographic waveform or other communication (including even embedding codes within the GPS data obtained by the GPS receiver of the device 800) which remotely disables the device, such as when capture or death is observed on the battlefield. In this fashion, the device 800 can be immediately and even remotely disabled permanently to frustrate use by an enemy. The IC or ASIC in the device can further be programmed to “self-destruct”, such as by wiping all of its program memory using a flash/volatile memory approach, application of a potential across certain portions of the memory cells, etc.

In terms of biometrics, the owner's voice data, fingerprint, or even retinal data can be used to aid in authentication. For example, retinal or fingerprint data may be obtained from an external device whose output is used to either authenticate or invalidate the user. With sufficient miniaturization, such devices may also conceivably be integrated into the device itself, such as where the aforementioned CMOS sensor is provided with sufficient resolution and an illumination source so as to be able to “read” the owners retina when the device 800 (and particularly the CMOS sensor) is place up to the owner's eye. The user may also be implanted with, ingest, or otherwise carry a miniature passive or active RFID device (e.g., “rice grain” size injected or implanted under the user's skin, such as is well known in the prior art for personnel identification and access control). The RFID device can then be used to as an electronic key to activate the device 800, such by passing that portion of their anatomy in close proximity to the device 800. The device 800 may emit an interrogation field which “wakes” the passive RFID device to emit a precoded data structure or protocol which is matched against a pre-stored or received value.

Other parameters or conditions (such as items (i)-(x) listed above) can also be used alone or in conjunction with the biometrics in order to control access to and/or transmission of messages or other functions associated with the device 800. Myriad such combinations will be recognized by those of ordinary skill given the present disclosure.

The device 800 may also be equipped with a miniature CMOS or CCD camera (and supporting processing, such as sample and hold circuitry, ADC, compression algorithm for reducing the storage size and bandwidth requirements for storage and transmission, etc.) capable of acquiring images local to the user and transmitting them to a remote location. Alternatively, the device 800 can receive external video or image data via the holographic data link and display it on the miniature display unit. Much like a conventional digital camera, the device 800 can also be programmed to store one or more images within the device for later retrieval. Such video and/or “stills” can also be acquired remotely, such as where the device 800 receives a holographically encoded signal from a remote device, the received signal encoding a command to initiate a certain event (e.g., “commence data acquisition at T=00:00:00 UTC time”). In this fashion, the owner can simply leave the device 800 at a given location, and then later remotely monitor that location.

The device 800 may also be equipped with a miniature solar cell (array) sufficient to provide power for at least some functions of the device. This cell or array can be used to “float ” the batteries previously described; i.e., to supplement and/or reduce the drain on the batteries during times when the cell output voltage is sufficient to drive a forward current. In one embodiment, well known Zener diodes are used; when the cell potential is sufficient to forward bias the diodes, current flows from the solar cells to the battery terminal(s) or other portions of the device 800. Such approaches are ubiquitous in the prior art, and accordingly not described further herein.

In another variant of the present invention, the device 800 may be configured to accommodate two or more air interfaces or RF paradigms. For example, the device 800 may be equipped with suitable signal processing and algorithms (such as on the aforementioned ASIC or SoC) to identify the appropriate radio interface and configuration, and adapt itself on-the-fly to utilize this interface. Such a software defined or controlled radio (SD/CR) is useful to avoid operators hunting for the appropriate type of radio, frequency, protocol, etc. (especially during the heat of battle where a holographic receiver may or may not be present), and is in one embodiment defined by the Joint Tactical Radio System (JTRS) requirement recently implemented by the U.S military. The JTRS is built upon the Software Communications Architecture (SCA). The SCA is an open architecture framework that tells designers how the various elements of hardware and software are to operate within the JTRS. The SCA enables programmable radios to load waveforms, run applications, and be networked into an integrated system. In JTRS, the term “waveform” describes the entire set of radio functions that occur from the user input to the RF output and vice-versa. A JTRS waveform is implemented as a re-useable, portable, executable software application that is independent of the JTR System operating system, middleware, and hardware. The software application waveforms, including the Wideband Networking Waveform (WNW), network services, and the programmable radio set (i.e., the traditional radio box) form the JTR set. The JTR sets, when networked with other JTR sets, becomes the JTRS. FIG. 8b illustrates this relationship. The SCA Hardware (HW) Framework assures that software written to the SCA standard will run on SCA-compliant hardware. Similarly, a set of software specifications are provided for software applications. The core framework illustrated in FIG. 8b provides an abstraction layer between the waveform application and JTR sets, enabling application porting to multiple vendor JTR sets.

One exemplary configuration of the JTRS radio SCA is described in detail in U.S. Patent Application Pub. No. 20030114163 to Bickle, et al. published Jun. 19, 2003 and entitled “Executable radio software system and method”, incorporated herein by reference in its entirety, which discloses an executable radio software system including a core framework layer responsive to one or more applications and a middleware layer. The core framework layer includes isolated platform dependent code in one or more files for a number of different platforms each selectively compilable by a directive to reduce the dependency of the core framework layer on a specific platform. See also U.S. Patent Application Pub. No. 20030177245 to Hansen published Sep. 18, 2003 and entitled “Intelligent network interface”, incorporated herein by reference in its entirety, which describes a JTRS network interface according to the SCA, and U.S. Patent Application Pub. No. 20040133554 to Linn, et al. published Jul. 8, 2004 entitled “Efficient file interface and method for providing access to files using a JTRS SCA core framework” incorporated by reference herein in its entirety, which discloses a system and method for accomplishing improved file access within the JTRS SCA system environment.

With advances in silicon process technology, integration, and memory storage capability and size, an entire (albeit limited) SD/CR device can be contained on a single integrated circuit or closely related set of integrated circuits (chipset), with all or portions of the aforementioned SCA residing on storage devices either integrated with this IC or in discrete memory devices. The SD/CR algorithms necessary for both identification and subsequent operation under the elected air interface can be readily contained in software, firmware, and/or hardware sized to fit within the device of FIG. 8 herein, although it will be recognized that other form factors may be used if desired. For example, well known miniature RF SoC devices, which effectively act as an RF transceiver front end, are available in packages on the order of millimeters in size in each dimension. Hence, the present invention contemplates use of a common baseband processor (e.g., DSP, RCF, or custom ASIC) coupled to a plurality of different RF transceiver hardware suites, all within the device 800. The baseband processor is also tasked with management of the SD/CR functionality, including receiving, analyzing and selecting the proper transceiver components and air interface for the desired communications.

Use of Other Carriers of Information

In general, the holographic technology of the present invention can be applied to any type of energy wave or beam that can be modulated to carry information.

For example, in addition to radio frequency (RF) electromagnetic energy, the present invention may be readily adapted to “acoustic” energy (e.g., pressure waves formed within a medium of propagation), such as for example sonar and other underwater sound sources. Such acoustic waves can be made noise-like with the present holographic technology, and therefore significantly more difficult to detect and acquire. Specific applications for such acoustic variants of the invention include military uses such as submarine sonar technology (e.g., on the active sonar array), sonobuoys, torpedoes (e.g., Mk-48 ADCAP or similar), air-dropped homing torpedoes, underwater or floating mines, and underwater communications (such as ship-to-ship covert communications systems), where the noise-modulated waveforms would be difficult to hear, recognize, and detect. For example, in an underwater communications (UWC) system, the creation of holographically encoded waveforms is completely analogous to that in the RF domain as described above. A vocoder/codec of the type ubiquitous in the electronic arts is used to encode the user's voice (or other data stream) into a digital baseband data set. This data is then phase coded with a phase code (whether all-real or complex), and then transformed to form the holographic waveforms. These waveforms may be stored and burst-transmitted for LPI against broadband noise detection systems such as a submarine broadband passive spherical or towed array, or rather may be transmitted continuously at very low power levels and very high code spread bandwidths (i.e., roughly the equivalent of UWB except for UWC).

Additionally, other types of sonar systems, such as those adapted for ocean contour mapping, depth detection, current profiling, marine life detection (e.g., so-called “fish finders”), or even high-frequency proximity detection sonar used for docking evolutions can utilize the present technology. For example, the Acoustic Doppler Current Profiling (ADCP) systems offered by Rowe-Deines Instruments, Inc. (RD Instruments) of San Diego, Calif. can be readily modified to include LPI signal processing according to the present invention, thereby providing an excellent LPI current profiler for use on, e.g., military submarines. U.S. Pat. No. 5,483,499 to Brumley, et al. issued Jan. 9, 1996 and entitled “Broadband acoustic Doppler current profiler” incorporated herein by reference in its entirety describes and exemplary broadband acoustic Doppler current profiling system compatible for such adaptation to holographically encoded waveforms. Specifically, the broadband waveforms generated by the device can be holographically encoded (e.g., phase coded and then mathematically transformed) to produce a broadband “noise” spectrum which is then modulated onto the transducer output. Sharper broadband pulses of the prior art can therefore be replaced by holographically encoded “slush” which is significantly more covert. The baseband spectrum of these waveforms can be used to determine range (roughly 2×, due to outbound and return propagation paths) as described elsewhere herein; i.e., using one or more artifacts such as a DC spike or Sin(x)/x distribution to determine baseband frequency offset (and hence distance with a known propagation speed). Doppler information recovery from these holographically encoded waveforms may also be provided using any number of methods, including e.g., (i) analysis of known duration pulses for temporal compression or expansion; or (ii) analysis of the baseband power spectrum to observe the effect on artifacts encoded into the baseband on transmission of the pulse (e.g., a shift up or down in the power spectrum in the received pulse versus the transmitted pulse).

Furthermore, the parent acoustic system may comprise any number of transducer configurations, including for example a phased array, spherical array, wide-aperture array (WAA), towed array, etc., especially since the holographic encoding is bearer-medium independent.

Additionally, the present invention teaches the use of acoustic “overlays” in order to further tailor the radiated acoustic signature or local acoustic environment. Such overlays may comprise, for example, the addition of masking or deception signals that are contemporaneously transmitted with the communications signals. These overlays may either (i) increase the ambient or background noise level within which the LPI communications signal propagates, and/or (ii) provide distractive or deceptive signals intended to cause any listening entity to consider alternative sources or reasons for the LPI signals.

As an example of the first use, a low intensity broadband (e.g., wide spectrum) signal may be radiated contemporaneously or otherwise incorporated into the LPI signals, thereby increasing the background ocean “din”. Care must be utilized in this approach, however, to avoid creating what appears as an acoustic “bright spot” on the listening entity's broadband sensors (e.g., submarine sonar “DIMUS” trace), in effect an acoustic marker which stands out over noise emanating from other azimuth/elevation coordinates.

As an example of the second use, natural sea sounds such as whale songs, dolphin chatter, or shrimp snapping (so called “biologics”) can be replicated and transmitted with the LPI signals in order to attempt to deceive any listener into believing (or at minimum, analyzing) that the source of the detected acoustic energy is natural in origin. Such biologic sounds can also perform the function of (i) above; i.e., their energy to some degree can mask the LPI signals due to increased background or ambient acoustic levels (db).

Furthermore, the deceptive overlays need not be limited to biologics. For example, a submarine or ship of one nationality may radiate broadband and/or narrowband noise signatures characteristic of another nationality or class of submarine or ship, in order to deceive the listening entity as to the true identity of the vessel. Since most if not all submarine/surface ship classification systems operate on acoustic signature (e.g., broadband signature, narrowband “tonals”, propulsion blade rate, transients, etc.), they can be fooled by a very silent platform having a first signature profile but radiating a second, more salient deceptive signature. For example, where the listeners are expecting to hear or detect a submarine having a particular signature, and there is a probability that the LPI signals may be detected if not “masked”, it may be desirable to emit the deceptive acoustic signature contemporaneously with the LPI signals, since it is highly unlikely that the listeners would analyze for LPI signals within the acoustic signature of an ostensibly friendly vessel.

In yet another aspect of the invention, the holographic techniques described herein may be applied to the modulation of microwaves (such as those used in radar) or so-called “millimeter waves” used in data transmission links for the purpose of creating noise-like signals that cannot be detected by interceptor technology. In the context of radar, the utility of such covert emission is self-evident. For example, since many military platforms utilize signals detection equipment to detect RF/electromagnetic signals and assess the nature of the threat (so-called “ELINT” and “SIGINT”), the ability to scan or interrogate in a substantially passive manner provides a huge tactical advantage.

Consider, for example, the foregoing submarine operating in coastal waters. Many defensive or military installations (or their patrolling surface vessels) use surface-search radars to scan for approaching ships, small boats, or other anomalies (such as submarine periscopes). Current state-of the art radars (including synthetic aperture radar or SAR, discussed below) can detect exceedingly small artifacts, including for example birds, small surface waves, etc. Yet all such prior art systems suffer from an active radiated energy profile; i.e., if the vessel creating the artifact (e.g., submarine) is properly equipped, it can detect the electronic signature of the coastal radar and mitigate its radar cross-section (RCS), such as by immediately lowering its sensors/periscope. Hence, under the prior art, the submarine enjoys the advantage of a “hit and run” RCS (i.e., a small RCS existing for only a very short period of time), thereby limiting its chances of being detected.

However, were the utility of the submarine's ELINT/SIGINT sensors defeated through the use of an undetectable (or at least LPI) radar system, the submarine may be provided with a false sense of security, thereby perhaps keeping its sensors/periscope in an exposed posture for a longer period of time. Since these sensors, typically housed in an extending mast, cannot be made completely “stealthy” (i.e., the RCS can never be completely eliminated) to a degree to defeat SAR and other comparable radars, the LPI radar system of the present invention would alter the balance of tactical advantage in such situations from the submarine to the scanning radar.

Other uses for the LPI radar of the present invention are also readily envisaged. For example, low-observable (stealth) aircraft such as the F-117 Nighthawk, F-22 Raptor and B-2 Spirit often severely limit “active” RF emissions during operations in order to maintain their covertness. This is particularly true of navigation and detection sensors; rather than use an active RF radar, passive systems such as a FLIR are substituted. However, in certain circumstances, it would be desirable to have a radar system (especially for long-range threat detection) if covertness could be maintained. The LPI radar system of the present invention affords such capabilities, since it effectively eliminates any traditional radar energy signature. Similarly, the aforementioned submarines or surface ships (e.g., SPY-1 A/D variants of Aegis phased array weapons system used in the latter) could be given a “passive” radar capability, something lacking in current submarine and naval radar technology.

In one exemplary embodiment, the holographic technology of the present invention is adapted to a Doppler-based radar system having an antenna/aperture, transmitter block, receiver block, signal converter (e.g., ADC, as required), and signal processing block. The holographic signal processing described previously herein may be performed in software, firmware, or hardware, or any combinations thereof. Herein lies a significant advantage of the present invention; i.e., that the baseband holographic signal processing can be performed largely independent of the carrier or bearer medium. In one embodiment, the holographic processing (including Fourier or Cosine transforms, etc.) is performed within the signal processor(s) (e.g., DSPs) of the signal processing block, along with the Doppler processing. In the case of Fourier transforms, this is accomplished using FFT signal processing algorithms of the type well known in the art. This approach advantageously requires a minimum of modification to existing systems, thereby enhancing retrofit capabilities.

Simple radar ranging can be performed by measuring the frequency offset in the baseband power spectrum as previously described herein. The ranging and Doppler measurement techniques described above in the acoustic domain for e.g., ADCP sonar may be readily extended to RF or microwave systems.

It will further be recognized that the present invention may be utilized in both pulsed and CW (continuous wave) systems if desired, the adaptation to each such system being readily accomplished given the present disclosure.

The present invention may also be adapted to SAR systems as well, such as for example the AN/APY-8 Lynx™ SAR manufactured by General Atomics Corporation of San Diego, Calif. Synthetic Aperture Radar (SAR) refers to a technique used to synthesize a very long antenna by combining signals (echoes) received by the radar antenna as it moves along its flight track. The term aperture refers to the opening used to collect the reflected energy that is used to form an image. In the case of radar, the aperture comprises the antenna. A synthetic aperture is constructed by moving a real aperture or antenna through a series of positions along the parent platform's flight track. As the radar moves, one or more RF pulses are transmitted at each position; the return echoes pass through the receiver and are retained in an “echo store.” Because the radar is moving relative to the target, the returned echoes are Doppler-shifted. Comparing the Doppler-shifted frequencies to a known or reference frequency allows returned signals to be “focused” on a single point, effectively increasing the length of the antenna that is imaging that particular point. This focusing operation, commonly known as SAR processing, is done digitally and matches the variation in Doppler frequency for each point in the image. This processing requires very precise knowledge of the relative motion between the platform and the imaged objects. However, the LPI signal processing required by the present invention can be readily accommodated in parallel with the SAR processing (e.g., using any number of readily available high-speed digital processors), thereby allowing for parallel aperture synthesis and holographic processing.

LPI radar may also be readily applied to weapons systems, such as those using active radar systems for terminal guidance, to increase their “stealthiness”. For example, active air-to-air systems such as the AAMRAAM, HARM, AIM-7 Sparrow, AIM-54C Phoenix, and the like can be readily modified to incorporate LPI holographic waveform and radar technology as taught herein. Anti-ship weapons such as the Tomahawk anti-ship missile (TASM) or UGM-84 Harpoon which utilize an active terminal phase seeker can also benefit significantly. Even traditionally passive systems such as the ALCM, Tomahawk (TLAM), or Joint Direct Attack Munition (JDAM) which utilize GPS, topographical contour and/or “scene” matching (e.g., TERCOM, DSMAC) can be adapted to include a “passive” radar system according to the present invention. For example, the passive LPI radar could be used in a confirmatory fashion for mid-course or terminal guidance (e.g., turned on/off in essence gathering periodic “snapshots” for analysis and comparison to GPS/TERCOM/DSMAC data), threat detection and avoidance (e.g., dynamic route alteration based on threats detected after launch but before terminal delivery), “stealth” communications or telemetry between the munition and its parent platform (or other PGMs en route to the same or different target); see.e.g., co-owned an co-pending U.S. Provisional Patent Application Ser. No. 60/537,166 filed Jan. 15, 2004 and entitled “APPARATUS AND METHODS FOR COMMAND, CONTROL, COMMUNICATIONS, AND INTELLIGENCE” previously incorporated herein, or for secure GPS communications to and from the PGM, etc. The LPI radar of the present invention could similarly be used to supplement or even replace the TERCOM radio altimeter present on the ALCM/TLAM or similar systems.

Additionally, remotely piloted vehicles (RPVs) and unmanned aerial vehicles (UAV/UCAV) such as for example the General Atomics Predator, Gnat, Prowler, and Altus units, or the Teledyne RQ-4 Global Hawk, can be equipped with the holographic radar and/or communications systems of the present invention. This provides such vehicles with enhanced stealth and covertness which current on-board radar or communications systems do not offer.

Anti-ground/airborne weapons deployed on low-orbit space systems such as the Space Shuttle or satellites may also utilize the LPI radar of the present invention for stealthy or passive radar target acquisition or guidance. For example, space-to-air weapons could utilize the LPI system to preclude detection of targeting or terminal guidance radars. Radar-based orbital intelligence satellites (such as the Lacrosse systems) or earth-mapping/resource detection may also benefit from the application of the present invention, in that covert radar mapping or ground penetrating radar scans may be desired by the overhead asset operator.

It will be recognized from the foregoing that myriad different uses for the LPI radar of the present invention may be found, all such uses being readily implemented by those of ordinary skill in the radar arts given the present disclosure.

In the context of millimeter wave or satellite data systems (such as used for long distance point-to-point backbone data transmission in high-speed data networks, or transmission of DSS content signals in a satellite TV network, for example), the present invention may also be used to increase the covertness of these transmissions, thereby increasingly frustrating attempts at surreptitious piracy or modification of the streamed data. The LPI and other features of the invention both reduce the likelihood of detection and the ability to “hack” into the data, thereby enhancing security. Furthermore, data transmitted using the LPI approach of the present invention may be encrypted and protected against corruption, surreptitious or otherwise, such as through use of well known encryption techniques (e.g., public/private keys, DES), or any other of a plethora of well known techniques. The present invention is also compatible with convolutional and other error correction techniques (such as systematic or non-systematic “turbo” codes) that, inter alia, enhance the robustness of the communications channel.

In another aspect, the holographic techniques of the invention can be applied to higher frequency electromagnetic radiation (EMR), including visible or non-visible light, gamma rays, and X-rays. Hence, LPI light/gamma/X-ray scanning or communication systems are readily produced. These EMR sources may be coherent or non-coherent. For example, a laser (coherent) system can use the present technology to produce an LPI light beam for scanning or other tasks, such as a laser rangefinder or target designator (“painter”) for, e.g., hand-held anti-armor or anti-aircraft weapons such as TOW, Javelin, or Stinger, battle tanks (such as the M1A2, Bradley, Stryker), aircraft (such as the AH-64Apache Longbow, AC-130 Spectre, etc.) or ships.

Integrated combat systems such as the planned Future Combat System, which integrates unmanned ground and aerial vehicles, can also benefit from use of the present invention. These devices would have the advantage of increased stealth and lethality as compared to existing “dirty” or non-LPI systems, thereby providing greater tactical advantage to the parent platform or user.

In yet another aspect of the invention, sub-atomic particle beams (e.g., electron/positron, neutron, proton, and even neutrino) can be modulated according to the holographic techniques previously described. As the use of particle beams and other matter waves become more prevalent, information can be modulated onto them as well, using various modulation schemes such as binary pulse amplitude. Since many of these beams move at speeds that are relativistic, information can be transferred at nearly the same speed as more traditional radio waves. Moreover, many of these particles (such as neutrinos) can penetrate planet-size objects with very low probability of interaction.

Exemplary Wired Applications

Although the previous embodiments of the invention are generally associated with wireless communications systems, the invention's application is not so limited. For example, it will be recognized that wired communication systems including but not limited to, e.g. RF coaxial cable systems, trans-oceanic cables, NAVY SOSUS fiber cable arrays, optical systems, and even standard “POTS” telephony systems can be used as the bearer medium for the holographic signals.

In cable applications (e.g., HFC networks), the invention advantageously facilitates the use of more efficient modulation techniques. For example, currently, 256 or 64QAM is used primarily for sending digital data downstream over a coaxial network because of its efficiency in supporting up to 28-mbps peak transfer rates over a single 6-MHz channel. However, its susceptibility to interference currently makes it ill suited for upstream transmissions. The present invention reduces that susceptibility. Likewise, VSB has traditionally been used by hybrid networks for upstream digital transmission because it is faster than the commonly used QPSK. However, VSB is also more susceptible to noise than QPSK, and so its use has been limited. Again, the invention reduces such susceptibility. Se, e.g., co-owned and co-pending U.S. patent application Ser. No. 10/763,113 filed Jan. 21, 2004 entitled “HOLOGRAPHIC NETWORK APPARATUS AND METHODS”, previously incorporated herein.

This invention also expands the capabilities of current communications systems without requiring the installation of an entire new system. This is further enhanced by the ability of the invention to utilize baseband modulations of any type including non-digital, analog amplitude and frequency modulations. For example, current telephone modems (e.g. 1200-bit modems) and paging systems use FSK signals. More secure transmission of data over these systems would facilitate expanded use. Furthermore, because holographic communication methods may also be used with amplitude-shift-keyed (ASK) signals, fiber optic systems may also utilize the techniques.

The holographic techniques can also be applied to Internet or other “un-trusted” network transactions in order to increase security, enhance redundancy (via convolution), etc. In addition to the aforementioned millimeter wave systems commonly used in portions of the network backbone, covert holographic communications may be initiated at other points in the network, even as far out on the network as the endpoints (i.e., user terminals). Hence, the present invention can be used to complement or supplant traditional security paradigms such as the Virtual Private Network (VPN), wherein users within a security perimeter may transfer encapsulated packetized data over an un-trusted network in a secure fashion to another security perimeter.

It will be recognized that while certain aspects of the invention are described in terms of a specific sequence of steps of a method, these descriptions are only illustrative of the broader methods of the invention, and may be modified as required by the particular application. Certain steps may be rendered unnecessary or optional under certain circumstances. Additionally, certain steps or functionality may be added to the disclosed embodiments, or the order of performance of two or more steps permuted. All such variations are considered to be encompassed within the invention disclosed and claimed herein.

While the above detailed description has shown, described, and pointed out novel features of the invention as applied to various embodiments, it will be understood that various omissions, substitutions, and changes in the form and details of the device or process illustrated may be made by those skilled in the art without departing from the invention. The foregoing description is of the best mode presently contemplated of carrying out the invention. This description is in no way meant to be limiting, but rather should be taken as illustrative of the general principles of the invention. The scope of the invention should be determined with reference to the claims.

1. Radio frequency communications apparatus adapted to holographically encode baseband data and transmit said encoded data;
wherein said holographically encoded data comprises a plurality of shaped pulses.

2. The apparatus of claim 1, wherein said plurality of shaped pulses comprise pulses having shaped amplitude.

3. The apparatus of claim 2, wherein individual ones of said pulses are of equal amplitude, yet varying polarity, said polarity being determined based at least in part on the value of a holographically encoded waveform corresponding thereto.

4. The apparatus of claim 1, wherein said apparatus generates a holographically encoded waveform, and individual ones of said pulses are of varying duration, said duration being related at least in part to the zero crossings of said waveform.

5. The apparatus of claim 2, wherein individual ones of said pulses are of varying duration and equal amplitude.

6. The apparatus of claim 2, wherein said shaped amplitude comprises varying the amplitude of each pulse according to a scheme.

7. The apparatus of claim 6, wherein said apparatus generates a holographically encoded waveform, and said scheme comprises varying the amplitude according to the average of said holographically encoded waveform between zero crossings thereof.

8. The apparatus of claim 1, wherein said apparatus generates a holographically encoded waveform, and individual ones of said pulses comprise short-duration pulses disposed substantially at respective ones of zero crossings of said waveform.

9. The apparatus of claim 8, wherein said short-duration pulses are substantially uniform in duration.

10. The apparatus of claim 8, wherein said short-duration pulses are substantially uniform in amplitude.

11. The apparatus of claim 8, wherein said pulses are varied in amplitude according to the average amplitude of said holographically encoded waveform between zero crossings thereof.

12. The apparatus of claim 9, wherein said short-duration pulses are substantially uniform in polarity.

13. The apparatus of claim 1, wherein said apparatus generates a holographically encoded waveform, and individual ones of said pulses comprise broadband Gaussian monopulses disposed substantially at respective ones of zero crossings of said waveform.

14. The apparatus of claim 4, wherein said holographically encoded waveform is produced by phase-coding said baseband data to produce first phase-coded data and subsequently performing at least one mathematical transform on said first phase-coded data.

15. The apparatus of claim 7, wherein said holographically encoded waveform is produced by phase-coding said baseband data to produce first phase-coded data and subsequently performing at least one mathematical transform on said first phase-coded data.

16. Radio frequency communications apparatus adapted to receive and decode holographically encoded signals that comprise a plurality of shaped pulses.

17. The apparatus of claim 16, wherein said decoding comprises (i) detecting said pulses, (ii) performing at least one mathematical inverse transform on said holographically encoded signals, and thereafter (iii) decoding using a first phase code to produce baseband data.

18. The apparatus of claim 17, wherein said plurality of shaped pulses comprises a plurality of pulses having constant amplitude but varying duration, said varying duration being related to the zero crossings of a holographically encoded waveform used to generate said pulses.

19. The apparatus of claim 17, wherein said plurality of shaped pulses comprises a plurality of pulses having substantially constant duration, said pulses being disposed substantially at the zero crossings of a holographically encoded waveform used to generate said pulses.

20. The apparatus of claim 17, plurality of shaped pulses comprises a plurality of pulses having an amplitude varied according to the average amplitude of a holographically encoded waveform used to generate said pulses, as measured between zero crossings of said waveform.
